(19) United States
(12) Patent Application Publication
(10) Pub. No.: US 2026/0262310 A1
(43) Pub. Date: Sep. 3, 2026

(54) IMAGING ELEMENT PACKAGE AND METHOD FOR MANUFACTURING SAME

(71) Applicant: SONY SEMICONDUCTOR SOLUTIONS CORPORATION, KANAGAWA (JP)

(72) Inventors: KOHYOH HOSOKAWA, KANAGAWA (JP); SHINGO HAMAGUCHI, KANAGAWA (JP); YUKI IKEBE, KUMAMOTO (JP); SATOSHI NOBUHARA, KUMAMOTO (JP); SHIGEKI ONO, KUMAMOTO (JP); KOJI TSUCHIYA, KANAGAWA (JP); TOSHIHIRO MURAYAMA, KANAGAWA (JP); KIWAMU ADACHI, KANAGAWA (JP)

(21) Appl. No.: 19/163,554

(22) PCT Filed: Feb. 5, 2024
(86) PCT No.: PCT/JP2024/003757

§ 371 Date: Sep. 9, 2025

(30) Foreign Application Priority Data
Mar. 17, 2023 (JP) 2023-043046

(51) Int. Cl. H10F 39/00

(52) U.S. Cl. CPC H10F 39/804; H10F 39/014

(57) ABSTRACT

An object of the present technology is to enhance the durability of a sealing glass in an imaging element package having a sealed structure achieved by the sealing glass. This imaging element package includes: a solid-state imaging element; a substrate where the solid-state imaging element is mounted; a sealing glass fixed to an imaging surface side of the solid-state imaging element; and a protection member that covers a ridge line of an upper surface of the sealing glass. The protection member covers the ridge line of the upper surface of the sealing glass to reduce the risk of crack formation in the sealing glass. The protection member may be a sealing resin per se, or may be provided separately from a sealing resin and arranged between the sealing resin and the solid-state imaging element. In the latter case, the protection member is expected to include, for example, a low-elasticity resin.

### TECHNICAL FIELD

The present technology relates to an imaging element package. Specifically, the present technology relates to an imaging element package that enhances the durability of a sealing glass, and a method for manufacturing the imaging element package.

### BACKGROUND ART

As existing imaging element packages, a structure where a sealing glass is fixed to an imaging surface side of a solid-state imaging element is known. For example, an imaging element package including a solid-state imaging element and a sealing glass having their respective side surfaces sealed with resin has been proposed (see, for example, Patent Document 1).

### CITATION LIST

### Patent Document

Patent Document 1: WO 2022/113813 A

### SUMMARY OF THE INVENTION

### Problems to be Solved by the Invention

In the above-described known technology, sealing the respective side surfaces of the solid-state imaging element and the sealing glass with resin protects the imaging surface of the solid-state imaging element. There is, however, a possibility that a crack may occur at a boundary between the sealing resin and the upper surface of the sealing glass, which negatively impacts the reliability of the imaging element package.

The present technology has been made in view of such circumstances, and it is therefore an object of the present technology to enhance the durability of a sealing glass in an imaging element package having a sealed structure achieved by the sealing glass.

### Solutions to Problems

The present technology has been made to solve the above-described problems, and a first aspect of the present technology is an imaging element package including: a solid-state imaging element; a substrate where the solid-state imaging element is mounted; a transparent member fixed to an imaging surface side of the solid-state imaging element; and a protection member that covers a ridge line of an upper surface of the transparent member. This configuration provides the effect of enhancing the durability of the transparent member in the imaging element package in which the transparent member is fixed to the imaging surface side of the solid-state imaging element.

Furthermore, in the first aspect, the protection member may include a sealing resin that covers a side surface of the transparent member and a side surface of the solid-state imaging element. This configuration provides the effect of enhancing the durability of the transparent member using the sealing resin.

Furthermore, the first aspect may further include a protruding member provided on the upper surface of the transparent member, along an inner periphery of the protection member. This configuration provides the effect of preventing the protection member from intruding into the inner periphery of the upper surface of the transparent member during the manufacturing process.

Furthermore, the first aspect may further include a sealing resin that covers at least a side surface of the solid-state imaging element, in which the protection member may be provided between the sealing resin and the solid-state imaging element. This configuration provides, by providing the protection member separately from the sealing resin, the effect of more effectively enhancing the durability of the transparent member.

Furthermore, in the first aspect, the protection member may include a low-elasticity resin. This configuration provides, by reducing the stress applied to the transparent member, the effect of more effectively enhancing the durability of the transparent member.

Furthermore, in the first aspect, the transparent member may include a groove provided on the upper surface of the transparent member, along an inner peripheral portion of the protection member. This configuration provides the effect of preventing the protection member from intruding into the inner periphery of the upper surface of the transparent member during the manufacturing process.

Furthermore, in the first aspect, the protection member may entirely cover a side surface of the transparent member, or may cover only an upper side portion of the side surface of the transparent member.

Furthermore, in the first aspect, at least a part of a side surface of the transparent member may have a tapered shape. This configuration provides, by reducing the stress applied to the upper surface portion of the transparent member, the effect of enhancing the durability of the transparent member.

Furthermore, in the first aspect, a recess positioned on an upper surface of the protection member, separated from the upper surface of the transparent member may be further included. This configuration provides the effect of reducing, through the protection member, the stress applied to the upper surface portion of the transparent member at the position of the recess.

Furthermore, in the first aspect, a low-elasticity resin that is embedded in the recess and has a lower elastic modulus than the protection member may be further included. This configuration provides the effect of reducing, through the protection member, the stress applied to the upper surface portion of the transparent member at the position of the recess while suppressing a deterioration of sealing performance caused by the protection member.

Furthermore, in the first aspect, the recess may be provided in a position surrounding a periphery of the transparent member. This configuration provides the effect of reducing, through the protection member, the stress applied to the entire upper surface portion of the transparent member at the position of the recess.

Furthermore, in the first aspect, the recess may be provided along a part of a periphery of the transparent member. This configuration provides the effect of reducing, through the protection member, the concentration of stress applied to the upper surface portion of the transparent member.

Furthermore, in the first aspect, the recess may have a groove shape. This configuration provides the effect of forming the recess through half-cutting of the protection member using a blade.

Furthermore, in the first aspect, the recess may be formed in a vertical or inclined direction relative to a side surface of the transparent member. This configuration provides the effect of reducing the stress applied in the vertical or inclined direction relative to the side surface of the transparent member.

Furthermore, a second aspect of the present technology is a method for manufacturing an imaging element package, the method including: mounting a solid-state imaging element on a substrate; fixing a transparent member to an imaging surface side of the solid-state imaging element; and forming a protection member that covers a ridge line of an upper surface of the transparent member. That is, this is a manufacturing method where, when manufacturing the above-described imaging element package, after the transparent member is fixed, the ridge line of the transparent member is covered with the protection member.

Furthermore, in the second aspect, the forming a protection member may include: forming a sealing resin that covers a side surface of the solid-state imaging element; forming a groove by removing a part of the sealing resin; and applying the protection member to the groove. That is, this is a manufacturing method where, when forming the groove to which the protection member is applied, only the sealing resin is removed.

Furthermore, in the second aspect, the forming a protection member may include: forming a sealing resin that covers a side surface of the solid-state imaging element; forming a groove by removing a part extending across the boundary between the sealing resin and the transparent member; and applying the protection member to the groove. That is, this is a manufacturing method where, when forming the groove to which the protection member is applied, the part extending across the boundary between the sealing resin and the transparent member is removed.

Furthermore, the second aspect may further include forming a recess on an upper surface of the protection member at a position separated from the upper surface of the transparent member. That is, this is a manufacturing method where after the transparent member is fixed, the ridge line of the transparent member is covered with the protection member, and then the recess is formed on the upper surface of the protection member at a position separated from the upper surface of the transparent member.

Furthermore, a third aspect of the present technology is a method for manufacturing an imaging element package, the method including: forming a protection member that covers a ridge line of an upper surface of a transparent member; and fixing the transparent member to an imaging surface side of a solid-state imaging element mounted on a substrate. That is, this is a manufacturing method where, when manufacturing the above-described imaging element package, after the ridge line of the upper surface of the transparent member is covered with the protection member, the transparent member is fixed.

### BRIEF DESCRIPTION OF DRAWINGS

FIG. 1 is a diagram illustrating an example of a structure of an imaging element package according to a first embodiment of the present technology.

FIG. 2 is a first diagram illustrating a first example of a method for manufacturing the imaging element package according to the first embodiment of the present technology.

FIG. 3 is a second diagram illustrating the first example of the method for manufacturing the imaging element package according to the first embodiment of the present technology.

FIG. 4 is a diagram illustrating a second example of the method for manufacturing the imaging element package according to the first embodiment of the present technology.

FIG. 5 is a diagram illustrating an example of a structure of an imaging element package according to a second embodiment of the present technology.

FIG. 6 is a first diagram illustrating an example of a method for manufacturing the imaging element package according to the second embodiment of the present technology.

FIG. 7 is a second diagram illustrating the example of the method for manufacturing the imaging element package according to the second embodiment of the present technology.

FIG. 8 is a diagram illustrating an example of a structure of an imaging element package according to a third embodiment of the present technology.

FIG. 9 is a first diagram illustrating an example of a method for manufacturing the imaging element package according to the third embodiment of the present technology.

FIG. 10 is a second diagram illustrating the example of the method for manufacturing the imaging element package according to the third embodiment of the present technology.

FIG. 11 is a third diagram illustrating the example of the method for manufacturing the imaging element package according to the third embodiment of the present technology.

FIG. 12 is a fourth diagram illustrating the example of the method for manufacturing the imaging element package according to the third embodiment of the present technology.

FIG. 13 is a diagram illustrating an example of a structure of an imaging element package according to a fourth embodiment of the present technology.

FIG. 14 is a first diagram illustrating an example of a method for manufacturing the imaging element package according to the fourth embodiment of the present technology.

FIG. 15 is a second diagram illustrating the example of the method for manufacturing the imaging element package according to the fourth embodiment of the present technology.

FIG. 16 is a third diagram illustrating the example of the method for manufacturing the imaging element package according to the fourth embodiment of the present technology.

FIG. 17 is a diagram illustrating an example of a structure of an imaging element package according to a fifth embodiment of the present technology.

FIG. 18 is a first diagram illustrating an example of a method for manufacturing the imaging element package according to the fifth embodiment of the present technology.

FIG. 19 is a second diagram illustrating the example of the method for manufacturing the imaging element package according to the fifth embodiment of the present technology.

FIG. 20 is a third diagram illustrating the example of the method for manufacturing the imaging element package according to the fifth embodiment of the present technology.

FIG. 21 is a fourth diagram illustrating the example of the method for manufacturing the imaging element package according to the fifth embodiment of the present technology.

FIG. 22 is a diagram illustrating an example of a structure of an imaging element package according to a sixth embodiment of the present technology.

FIG. 23 is a first diagram illustrating an example of a method for manufacturing the imaging element package according to the sixth embodiment of the present technology.

FIG. 24 is a second diagram illustrating the example of the method for manufacturing the imaging element package according to the sixth embodiment of the present technology.

FIG. 25 is a third diagram illustrating the example of the method for manufacturing the imaging element package according to the sixth embodiment of the present technology.

FIG. 26 is a fourth diagram illustrating the example of the method for manufacturing the imaging element package according to the sixth embodiment of the present technology.

FIG. 27 is a diagram illustrating an example of a structure of an imaging element package according to a seventh embodiment of the present technology.

FIG. 28 is a first diagram illustrating an example of a method for manufacturing the imaging element package according to the seventh embodiment of the present technology.

FIG. 29 is a second diagram illustrating the example of the method for manufacturing the imaging element package according to the seventh embodiment of the present technology.

FIG. 30 is a third diagram illustrating the example of the method for manufacturing the imaging element package according to the seventh embodiment of the present technology.

FIG. 31 is a fourth diagram illustrating the example of the method for manufacturing the imaging element package according to the seventh embodiment of the present technology.

FIG. 32 is a diagram illustrating an example of a structure of an imaging element package according to a first modification of the seventh embodiment of the present technology.

FIG. 33 is a diagram illustrating an example of a method for manufacturing a sealing glass 202 according to the first modification of the seventh embodiment of the present technology.

FIG. 34 is a diagram illustrating an example of a structure of an imaging element package according to a second modification of the seventh embodiment of the present technology.

FIG. 35 is a diagram illustrating an example of a method for manufacturing a sealing glass 203 according to the second modification of the seventh embodiment of the present technology.

FIG. 36 is a diagram illustrating an example of a structure of an imaging element package according to an eighth embodiment of the present technology.

FIG. 37 is a cross-sectional view illustrating an example of a method for manufacturing the imaging element package according to the eighth embodiment of the present technology.

FIG. 38 is a diagram illustrating an example of a structure of an imaging element package according to a ninth embodiment of the present technology.

FIG. 39 is a cross-sectional view illustrating an example of a method for manufacturing the imaging element package according to the ninth embodiment of the present technology.

FIG. 40 is a diagram illustrating an example of a structure of an imaging element package according to a tenth embodiment of the present technology.

FIG. 41 is a cross-sectional view illustrating an example of a method for manufacturing the imaging element package according to the tenth embodiment of the present technology.

FIG. 42 is a diagram illustrating an example of a structure of an imaging element package according to an eleventh embodiment of the present technology.

FIG. 43 is a cross-sectional view illustrating an example of a method for manufacturing the imaging element package according to the eleventh embodiment of the present technology.

FIG. 44 is a diagram illustrating an example of a structure of an imaging element package according to a twelfth embodiment of the present technology.

FIG. 45 is a cross-sectional view illustrating an example of a method for manufacturing the imaging element package according to the twelfth embodiment of the present technology.

FIG. 46 is a plan view illustrating an example of a structure of an imaging element package according to a thirteenth embodiment of the present technology.

### MODE FOR CARRYING OUT THE INVENTION

Hereinafter, modes for carrying out the present technology (hereinafter referred to as embodiments) will be described. The description will be given in the following order.
1. First embodiment (an example of a structure where the sealing resin covers the ridge line of the upper surface of the sealing glass)
2. Second embodiment (an example of a structure where the dam is formed on the upper surface of the sealing glass according to the first embodiment)
3. Third embodiment (an example of a structure where the glass protection member covering the ridge line of the upper surface and the side surface of the sealing glass is formed and then fixed to the solid-state imaging element)
4. Fourth embodiment (an example of a structure where after the sealing glass is fixed to the solid-state imaging element, the glass protection member covering the ridge line of the upper surface and the side surface of the sealing glass is formed)
5. Fifth embodiment (an example of a structure where the groove is formed on the upper surface of the sealing glass according to the third embodiment)
6. Sixth embodiment (an example of a structure where the glass protection member covering the ridge line of the upper surface and only the upper portion of the side surface of the sealing glass is fixed to the solid-state imaging element)
7. Seventh embodiment (an example of a structure where the sealing glass has a tapered side surface according to the third embodiment)
8. Eighth embodiment (an example where, in a structure where the sealing resin covers the ridge line of the upper surface of the sealing glass, the recess is provided on the upper surface of the sealing resin at a position separated from the upper surface of the sealing glass, and the low-elasticity resin is embedded in the recess)
9. Ninth embodiment (an example where, in a structure where the sealing resin covers the ridge line of the upper surface of the sealing glass, the recess is provided on the upper surface of the sealing resin at a position separated from the upper surface of the sealing glass)
10. Tenth embodiment (an example where, in a structure where the sealing resin covers the side surface of the sealing glass, the recess is provided on the upper surface of the sealing resin at a position separated from the upper surface of the sealing glass, and the low-elasticity resin is embedded in the recess)
11. Eleventh embodiment (an example where, in a structure where the sealing resin covers the side surface of the sealing glass, the recess is provided on the upper surface of the sealing resin at a position separated from the upper surface of the sealing glass)
12. Twelfth embodiment (an example where, in a structure where the sealing resin covers the side surface of the sealing glass, the recess is formed on the upper surface of the sealing resin at a position separated from the upper surface of the sealing glass through molding along with the sealing resin)
13. Thirteenth embodiment (an example where variations in the position of the recess positioned on the upper surface of the sealing resin, separated from the upper surface of the sealing glass)

### 1. First Embodiment

### Structure of Imaging Element Package

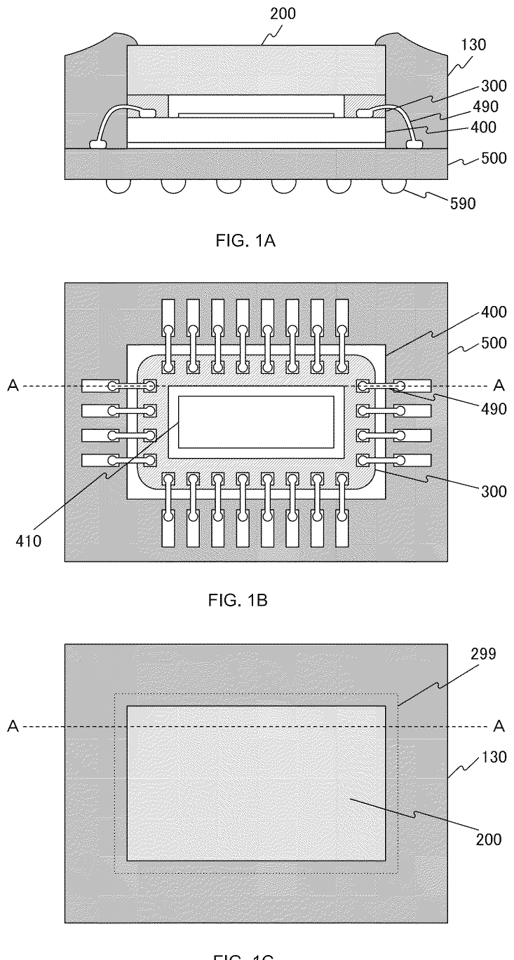

FIG. 1 is a diagram illustrating an example of a structure of an imaging element package according to the first embodiment of the present technology. Of the drawing, a is a cross-sectional view of the imaging element package taken along line A-A. Of the drawing, b and c are top views of the imaging element package. Note that b of the drawing illustrates a state where a sealing glass and a sealing resin are removed.

The imaging element package according to the first embodiment includes a substrate 500, a solder ball 590, a solid-state imaging element 400, a bonding wire 490, a rib member 300, a sealing glass 200, and a sealing resin 130.

The solid-state imaging element 400 is a semiconductor chip including an imaging surface where a plurality of pixels is arranged in an array. Examples of the solid-state imaging element 400 include, for example, a complementary metal-oxide-semiconductor (CMOS) image sensor, a charge-coupled device (CCD) image sensor, and the like.

The substrate 500 is a substrate where the solid-state imaging element 400 is mounted. The solid-state imaging element 400 is mounted on the substrate 500 via, for example, a die-bonding resin. Furthermore, electrical connections between the substrate 500 and the solid-state imaging element 400 are established via the bonding wire 490. Furthermore, for example, the solder ball 590 is formed on the back surface of the substrate 500 to establish electrical connections with the outside of the package. Note that, here, a ball grid array (BGA) structure using the solder ball 590 is assumed; however, it is also possible to use other structures, such as a land grid array (LGA) structure using a land instead of the solder ball 590.

The rib member 300 is an adhesive used for attaching the sealing glass 200 to the solid-state imaging element 400. The rib member 300 insulates and seals pads on the solid-state imaging element 400 side. Note that, as the rib member 300, it is possible to use, for example, a mixed resin obtained by mixing thermosetting acrylic-based and epoxy-based resins, which partially cures when exposed to a UV dose of 1 J/cm² or higher and begins to undergo thermosetting at 50° C. or higher.

The sealing glass 200 is a plate-like transparent member for protecting the imaging surface of the solid-state imaging element 400. In this structure example, placing the rib member 300 between the solid-state imaging element 400 and the sealing glass 200 achieves an imaging element package with a hollow sealing structure having a space formed between the solid-state imaging element 400 and the sealing glass 200. Note that the sealing glass 200 is an example of the transparent member recited in the claims.

The sealing resin 130 is a molding resin formed to surround the outer periphery of the side surfaces of the solid-state imaging element 400 and the sealing glass 200. The sealing resin 130 insulates and seals the pads on the solid-state imaging element 400 side. As the sealing resin 130, it is possible to use, for example, a thermosetting epoxy-based resin that begins to undergo thermosetting at 50° C. or higher. Note that the sealing resin 130 is an example of the protection member recited in the claims.

In the imaging element package according to the first embodiment, the sealing resin 130 is formed to cover a ridge line 299 of the upper surface of the sealing glass 200. This configuration can reduce stress by eliminating the edge of the bonded area between the side surface of the sealing glass 200 and the sealing resin 130, thereby reducing the risk of crack formation in the sealing glass 200. That is, the risk of crack formation is reduced by shifting the maximum stress point to the inner side of the surface of the sealing glass 200 that is stable as a substance.

### Method for Manufacturing Imaging Element Package

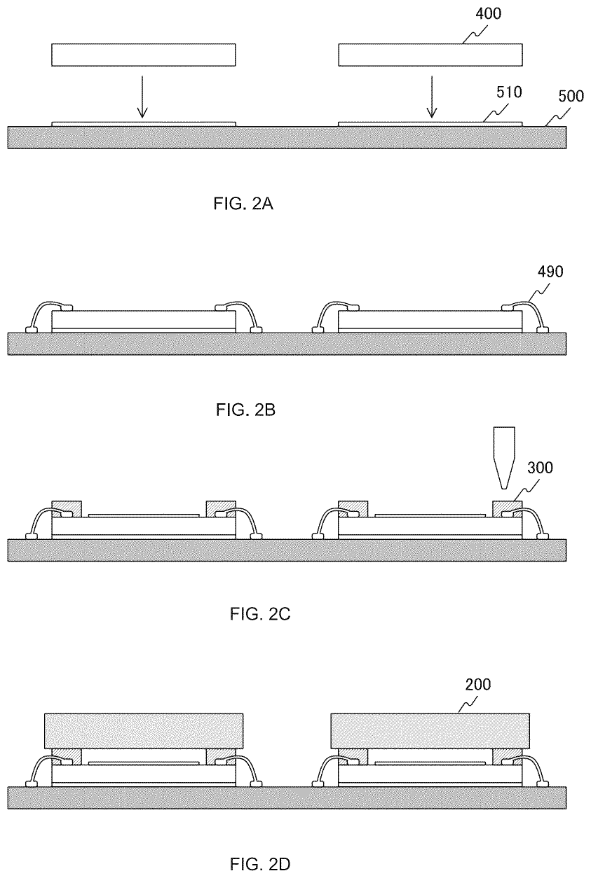

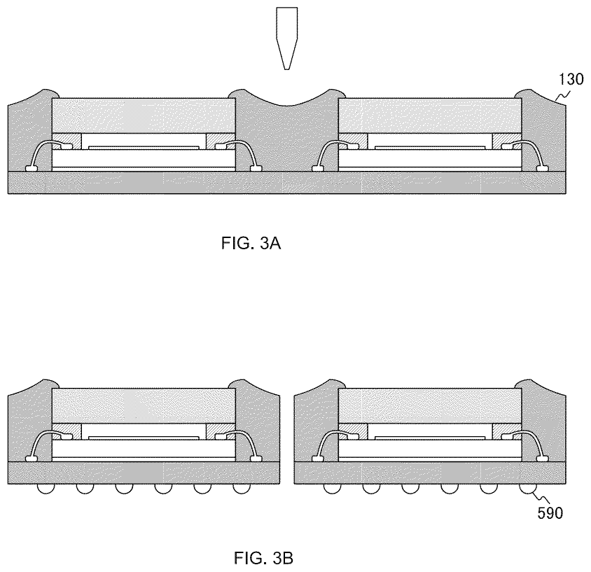

FIGS. 2 and 3 are diagrams illustrating a first example of a method for manufacturing the imaging element package according to the first embodiment of the present technology.

First, as illustrated in a of the drawing, the solid-state imaging element 400 is mounted on the substrate 500 via a die-bonding resin 510.

Then, as illustrated in b of the drawing, the pads on the solid-state imaging element 400 side and the pads on the substrate 500 side are electrically connected by the bonding wire 490.

Then, as illustrated in c of the drawing, the rib member 300 is applied to the pads on the solid-state imaging element 400 side.

Then, as illustrated in d of the drawing, the sealing glass 200 formed by cutting a glass plate into pieces of glass is mounted on the solid-state imaging element 400 via the rib member 300, and the resultant structure is thermally cured.

Thereafter, as illustrated in e of the drawing, the sealing resin 130 is applied to surround the outer periphery of the side surfaces of the solid-state imaging element 400 and the sealing glass 200. At this time, the sealing resin 130 is formed to cover the ridge line of the upper surface of the sealing glass 200.

Then, as illustrated in f of the drawing, the solder ball 590 is mounted on the lower surface of the substrate 500, and the resultant structure is diced into individual imaging element packages.

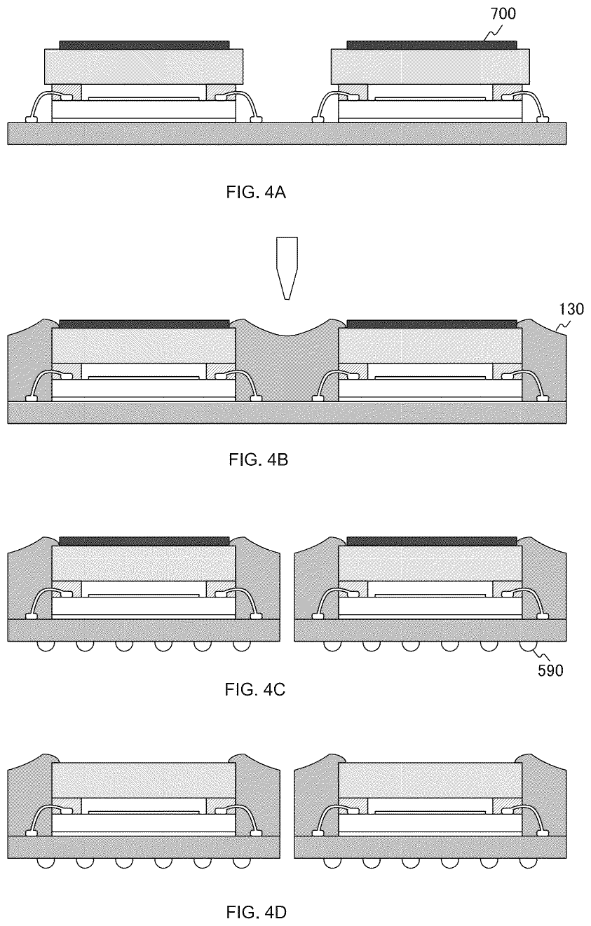

FIG. 4 is a diagram illustrating a second example of the method for manufacturing the imaging element package according to the first embodiment of the present technology.

The first half of this manufacturing method according to the second example is similar to that of the first example described above, and thus a detailed description thereof will be omitted.

After the sealing glass 200 is mounted on the solid-state imaging element 400, as illustrated in e of the drawing, a protective tape 700 is attached to the upper surface of the solid-state imaging element 400.

Thereafter, as illustrated in f of the drawing, the sealing resin 130 is applied to surround the outer periphery of the side surfaces of the solid-state imaging element 400 and the sealing glass 200. At this time, the sealing resin 130 is formed to cover the ridge line of the upper surface of the sealing glass 200. The sealing resin 130, however, is not applied to the portion where the protective tape 700 is attached.

Then, as illustrated in g of the drawing, the solder ball 590 is mounted on the lower surface of the substrate 500, and the resultant structure is diced into individual imaging element packages.

Then, as illustrated in h of the drawing, by removing the protective tape 700, the imaging element package is formed.

As described above, according to the first embodiment of the present technology, it is possible to reduce stress by covering the ridge line 299 of the upper surface of the sealing glass 200 with the sealing resin 130, thereby reducing the risk of crack formation in the sealing glass 200.

### 2. Second Embodiment

In the first embodiment described above, to form the sealing resin 130 to cover the ridge line 299 of the upper surface of the sealing glass 200, the sealing resin 130 is applied to surround the outer periphery of the side surfaces of the solid-state imaging element 400 and the sealing glass 200.

At that time, it is necessary to properly control the application range of the sealing resin 130. In the second embodiment, the amount of the sealing resin 130 is controlled by forming a dam on the upper surface of the sealing glass 200 according to the first embodiment described above.

### Structure of imaging element package

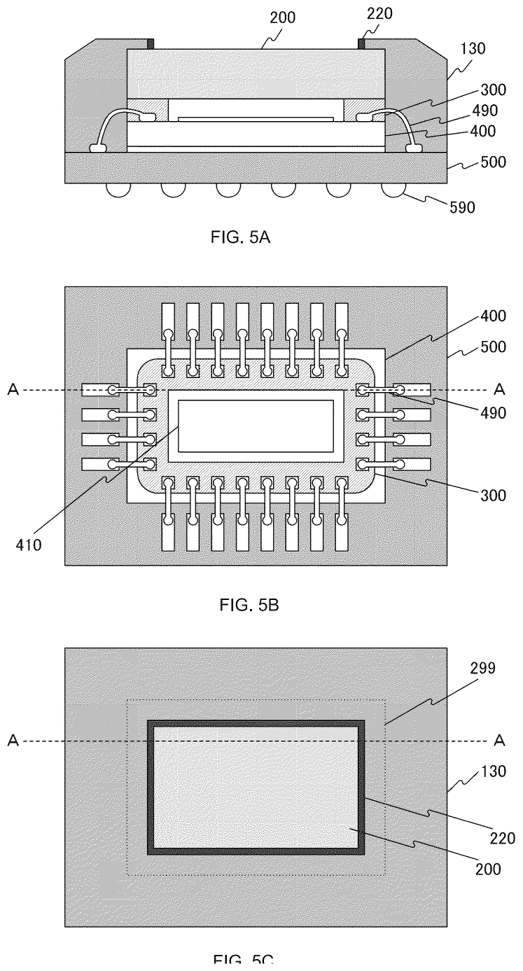

FIG. 5 is a diagram illustrating an example of a structure of an imaging element package according to the second embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the second embodiment, a dam 220 is additionally formed on the upper surface of the sealing glass 200, based on the structure of the first embodiment described above. This configuration can properly control the application amount of the sealing resin 130. As illustrated in c of the drawing, the dam 220 is provided on the upper surface of the sealing glass 200 and along the inner periphery of the sealing resin 130. As the dam 220, it is possible to use, for example, thermosetting resin. Note that the dam 220 is an example of the protruding member recited in the claims. The components other than the dam 220 are similar to those of the first embodiment, and thus a detailed description thereof will be omitted.

### Method for Manufacturing Imaging Element Package

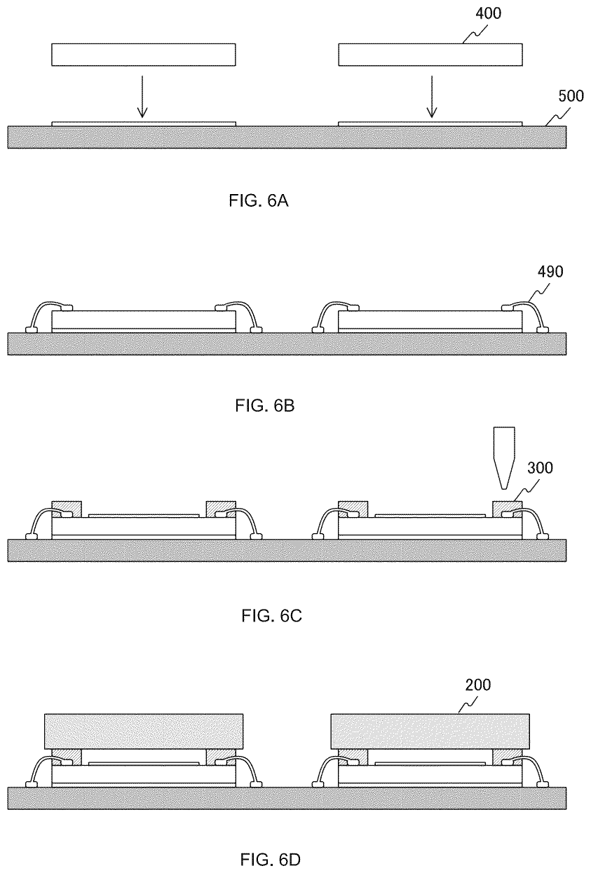

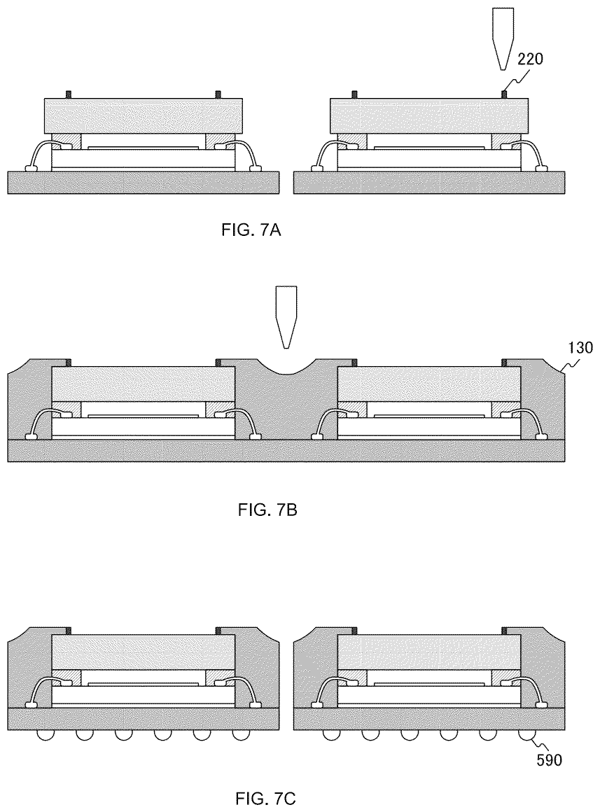

FIGS. 6 and 7 are diagrams illustrating an example of a method for manufacturing the imaging element package according to the second embodiment of the present technology.

The first half of this manufacturing method according to the second embodiment is similar to that of the first embodiment described above, and thus a detailed description thereof will be omitted.

After the sealing glass 200 is mounted on the solid-state imaging element 400, as illustrated in e of the drawing, resin for forming the dam 220 is applied to the upper surface of the solid-state imaging element 400.

Thereafter, as illustrated in f of the drawing, the sealing resin 130 is applied to surround the outer periphery of the side surfaces of the solid-state imaging element 400 and the sealing glass 200. At that time, the sealing resin 130 is formed to cover the ridge line of the upper surface of the sealing glass 200, but is controlled to ensure that the sealing resin 130 does not overflow past the dam 220.

Then, as illustrated in g of the drawing, the solder ball 590 is mounted on the lower surface of the substrate 500, and the resultant structure is diced into individual imaging element packages.

As described above, according to the second embodiment of the present technology, by forming the dam 220 on the upper surface of the sealing glass 200, it is possible to properly control the amount of resin when the sealing resin 130 is formed to cover the ridge line of the upper surface of the sealing glass 200.

### 3. Third Embodiment

In the first and second embodiments described above, a structure where the ridge line of the upper surface and the side surface of the sealing glass 200 are covered with the sealing resin 130 is assumed; however, an epoxy resin is commonly used as the sealing resin 130. Therefore, there is a possibility that oxidative degradation caused by thermal history may result in a rise in elastic modulus, leading to crack formation in the sealing glass 200. Therefore, in the following embodiment, a structure where the ridge line of the upper surface and the side surface of the sealing glass 200 are covered with a low-elasticity resin or the like is assumed.

### Structure of Imaging Element Package

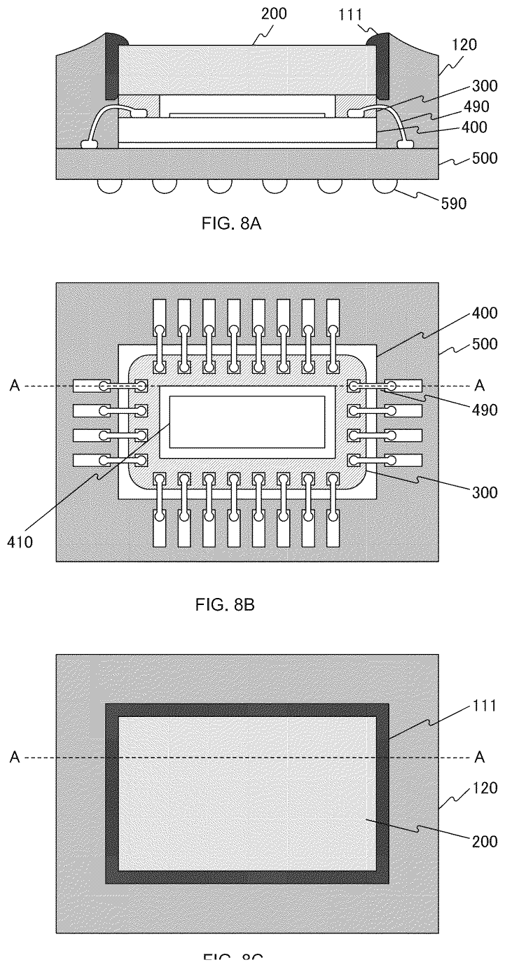

FIG. 8 is a diagram illustrating an example of a structure of an imaging element package according to the third embodiment of the present technology. Of the drawing, a is a cross-sectional view of the imaging element package taken along line A-A. Of the drawing, b and care top views of the imaging element package. Note that b of the drawing illustrates a state where the sealing glass and the sealing resin are removed.

In the third embodiment, the imaging element package includes a glass protection member 111 and a sealing resin 120 instead of the sealing resin 130 of the first embodiment described above.

The glass protection member 111 is a protection member that covers the ridge line of the upper surface and the entire side surface of the sealing glass 200. The glass protection member 111 functions as a stress relief layer to prevent crack formation in the sealing glass 200. Furthermore, a function that prevents separation at the boundary between the sealing glass 200 and the glass protection member 111 is achieved by covering the ridge line of the upper surface of the sealing glass 200. Furthermore, a function that blocks unwanted light to reduce flare is achieved by covering the outer periphery of the upper surface of the sealing glass 200 with the glass protection member 111.

As the glass protection member 111, it is desirable to use a material having low elasticity, high heat resistance, and strong resistance to oxidative degradation, and a low-elasticity silicon-based resin is assumed, for example. Furthermore, by taking viscosity and thixotropy into account, it is possible to control wet spreading when applying to the upper surface of the sealing glass 200. Note that the glass protection member 111 is an example of the protection member recited in the claims.

The sealing resin 120 is a molding resin formed to surround the outer periphery of the side surfaces of the glass protection member 111 and the solid-state imaging element 400. As the sealing resin 120, a material similar to the sealing resin 130 of the first embodiment described above can be used, but the sealing resin 120 is different from the sealing resin 130 in that the ridge line of the upper surface of the sealing glass 200 is not covered.

Note that the present embodiment is similar to the first embodiment described above except that the glass protection member 111 and the sealing resin 120 are provided instead of the sealing resin 130, and thus a detailed description thereof will be omitted.

### Method for Manufacturing Imaging Element Package

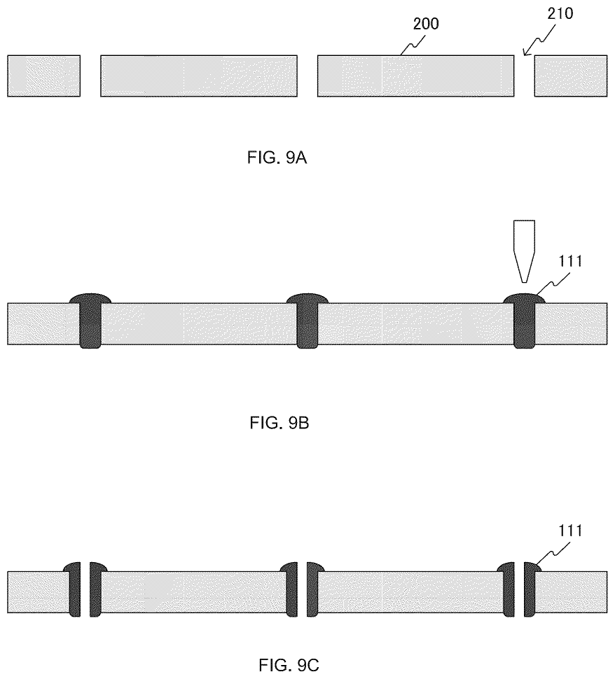

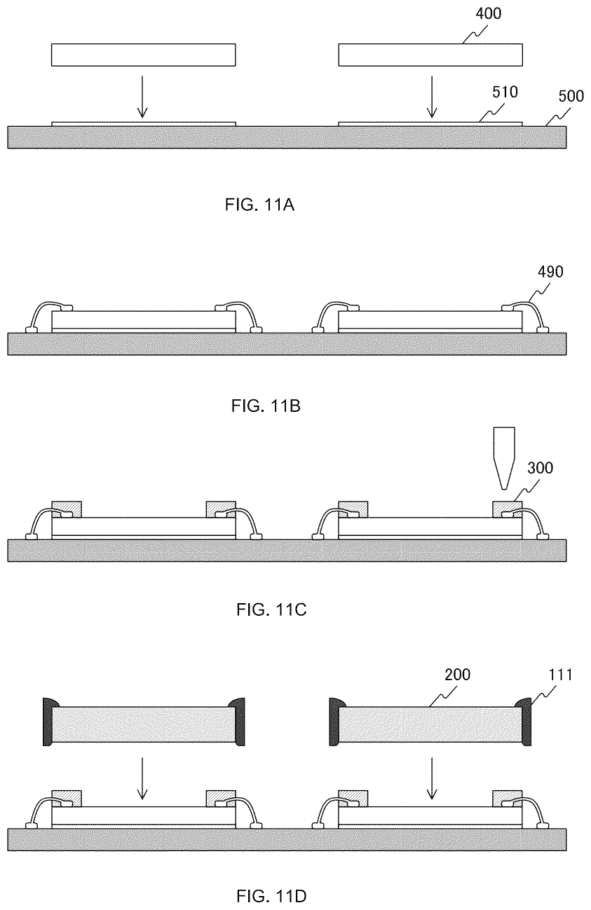

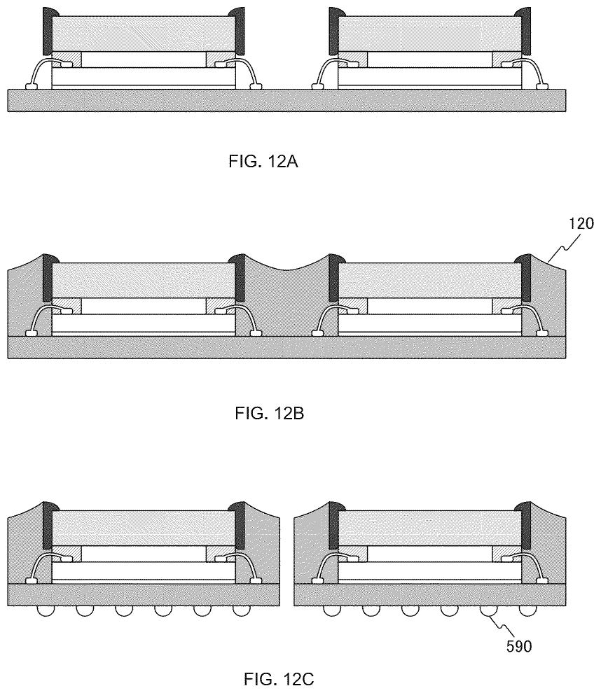

FIGS. 9 to 12 are diagrams illustrating an example of a method for manufacturing the imaging element package according to the third embodiment of the present technology.

In the third embodiment, it is assumed that the glass protection member 111 is formed before the sealing glass 200 is fixed to the solid-state imaging element 400.

Therefore, as illustrated in a of FIG. 9 and FIG. 10, a glass plate with dicing tape applied to the back surface undergoes full-cut dicing to form a groove 210 between the sealing glasses 200.

Then, as illustrated in b of the drawing, the glass protection member 111 is applied to each groove 210 to cover the ridge line of the upper surface and the side surface of the sealing glass 200. Thereafter, the glass protection member 111 is cured through ultraviolet irradiation or heating, or a combination of ultraviolet irradiation and heating.

Then, as illustrated in c of the drawing, the glass protection member 111 is cut into individual pieces using a dicing blade that is narrower than the blade used for the dicing to ensure that the glass protection member 111 remains on the side surface of the sealing glass 200.

On the other hand, as illustrated in d of the drawing, the solid-state imaging element 400 is mounted on the substrate 500 via the die-bonding resin 510.

Then, as illustrated in e of the drawing, the pads on the solid-state imaging element 400 side and the pads on the substrate 500 side are electrically connected by the bonding wire 490.

Then, as illustrated in f of the drawing, the rib member 300 is applied to the pads on the solid-state imaging element 400 side.

Then, as illustrated in g and h of the drawing, the sealing glass 200 with the glass protection member 111 formed thereon is mounted on the solid-state imaging element 400 via the rib member 300, and the resultant structure is thermally cured.

Thereafter, as illustrated in i of the drawing, the sealing resin 120 is applied to surround the outer periphery of the side surfaces of the solid-state imaging element 400 and the sealing glass 200. However, the sealing resin 120 does not need to cover the ridge line of the upper surface of the sealing glass 200.

Then, as illustrated in j of the drawing, the solder ball 590 is mounted on the lower surface of the substrate 500, and the resultant structure is diced into individual imaging element packages.

As described above, according to the third embodiment of the present technology, it is possible to reduce generated stress by covering the ridge line of the upper surface of the sealing glass 200 with the glass protection member 111, thereby reducing the risk of crack formation in the sealing glass 200 more effectively.

### 4. Fourth Embodiment

In the third embodiment described above, it is assumed that after the glass protection member 111 is formed on the sealing glass 200, the resultant structure is fixed to the solid-state imaging element 400; however, this order may be reversed. In the fourth embodiment, it is assumed that after the sealing glass 200 is fixed to the solid-state imaging element 400, the glass protection member is formed.

### Structure of Imaging Element Package

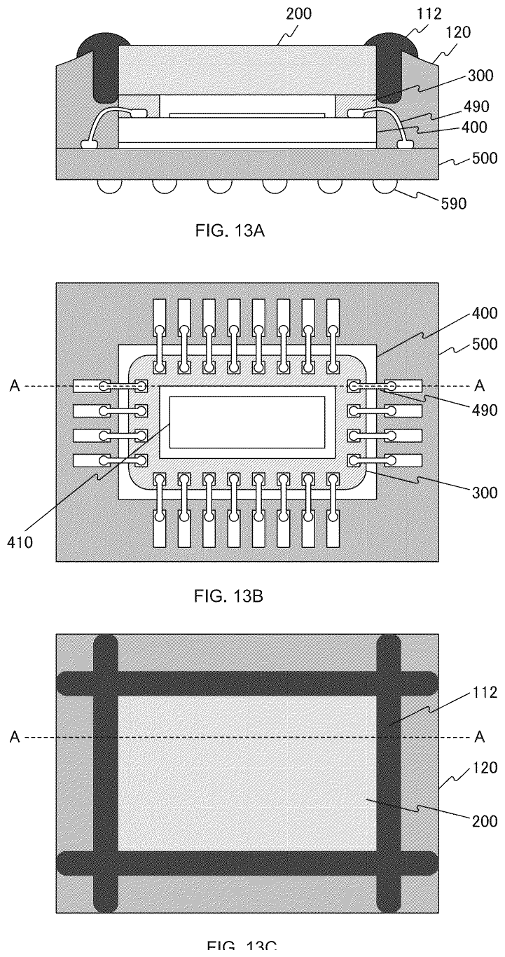

FIG. 13 is a diagram illustrating an example of a structure of an imaging element package according to the fourth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the fourth embodiment, the imaging element package includes a glass protection member 112 instead of the glass protection member 111 of the third embodiment described above. In the third embodiment described above, since after the glass protection member 111 is formed on the sealing glass 200, the resultant structure is fixed to the solid-state imaging element 400, the glass protection member 111 is formed along the sealing glass 200. On the other hand, in the fourth embodiment, after the sealing glass 200 is fixed to the solid-state imaging element 400, the glass protection member 112 is formed, which makes the region where the glass protection member 112 is formed different from that of the third embodiment. Note that the glass protection member 112 is an example of the protection member recited in the claims.

Note that, in the fourth embodiment, the glass protection member 112 is provided instead of the glass protection member 111 of the third embodiment described above; however, the same material can be used for both. Furthermore, the other components are similar to those of the third embodiment described above, and thus a detailed description thereof will be omitted.

### Method for Manufacturing Imaging Element Package

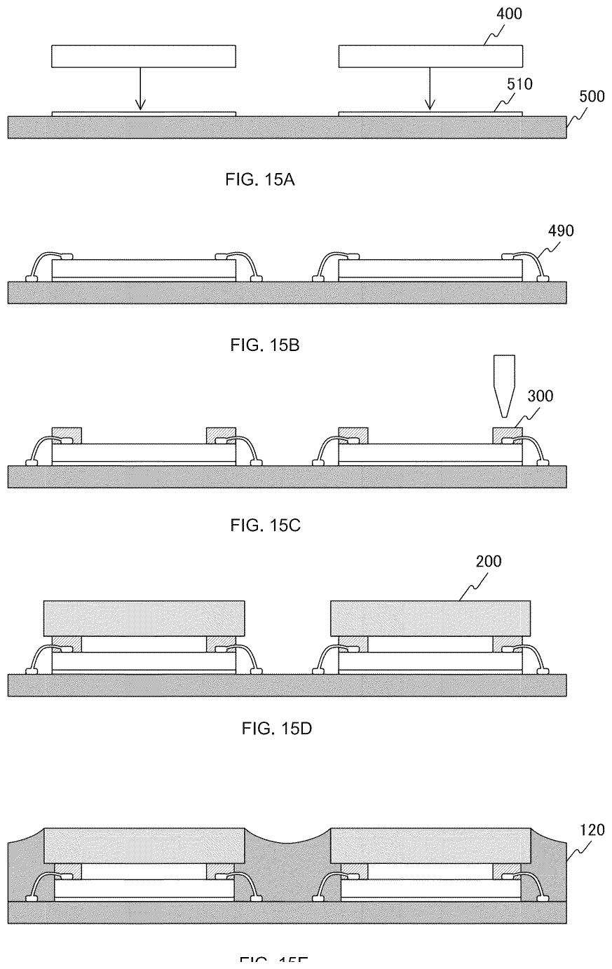

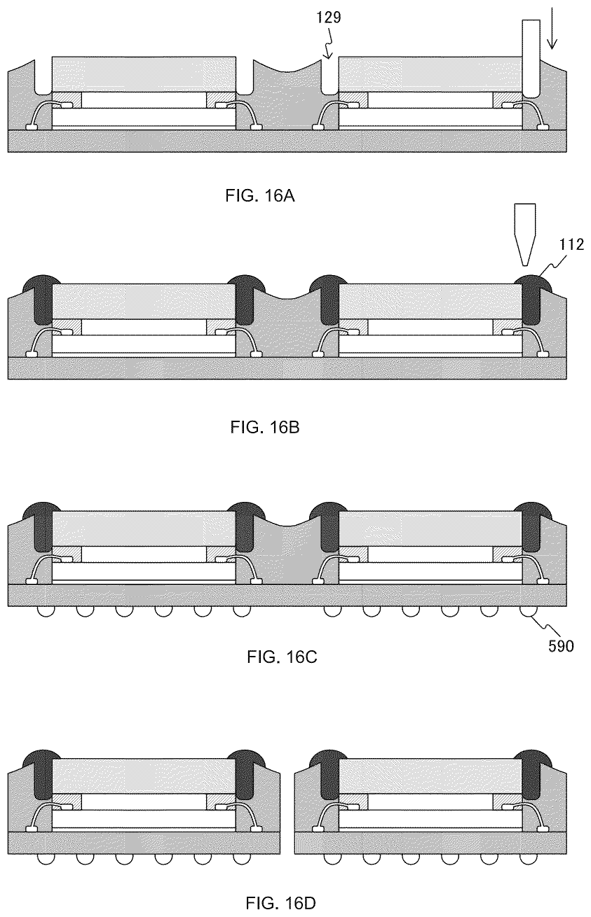

FIGS. 14 to 16 are diagrams illustrating an example of a method for manufacturing the imaging element package according to the fourth embodiment of the present technology.

In the fourth embodiment, since it is assumed that after the sealing glass 200 is fixed to the solid-state imaging element 400, the glass protection member 112 is formed, as illustrated in FIG. 14, the glass plate with the dicing tape applied to the back surface undergoes full-cut dicing to form the groove 210 between the sealing glasses 200.

Then, as illustrated in a of the drawing, the solid-state imaging element 400 is mounted on the substrate 500 via the die-bonding resin 510.

Then, as illustrated in b of the drawing, the pads on the solid-state imaging element 400 side and the pads on the substrate 500 side are electrically connected by the bonding wire 490.

Then, as illustrated in c of the drawing, the rib member 300 is applied to the pads on the solid-state imaging element 400 side.

Then, as illustrated in d of the drawing, the sealing glass 200 formed by cutting the glass plate into pieces of glass is mounted on the solid-state imaging element 400 via the rib member 300, and the resultant structure is thermally cured.

Thereafter, as illustrated in e of the drawing, the sealing resin 120 is applied to surround the outer periphery of the side surfaces of the solid-state imaging element 400 and the sealing glass 200. However, the sealing resin 120 does not need to cover the ridge line of the upper surface of the sealing glass 200.

Then, as illustrated in f of the drawing, a groove 129 is formed along the outer peripheral portion of the sealing glass 200 using a dicing blade. When the groove 129 is formed, only the sealing resin 120 may be removed by dicing, or a part extending across the boundary between the sealing glass 200 and the sealing resin 120 may be removed. In either case, in the fourth embodiment, the entire side surface of the sealing glass 200 is exposed as the groove 129.

Then, as illustrated in g of the drawing, the glass protection member 112 is applied to the groove 129, and the resultant structure is thermally cured.

Then, as illustrated in h of the drawing, the solder ball 590 is mounted on the lower surface of the substrate 500.

Then, as illustrated in i of the drawing, the resultant structure is diced into individual imaging element packages.

As described above, according to the fourth embodiment of the present technology, it is possible to reduce generated stress by covering the ridge line of the upper surface of the sealing glass 200 with the glass protection member 112, thereby reducing the risk of crack formation in the sealing glass 200 more effectively.

### 5. Fifth Embodiment

In the third embodiment described above, it is assumed that the glass protection member 111 is formed on the sealing glass 200; however, there is a possibility that liquid resin may cause wet spreading when applied as the glass protection member.

Therefore, in the fifth embodiment, it is assumed that a groove for preventing wet spreading is provided on the upper surface of the sealing glass 200.

### Structure of Imaging Element Package

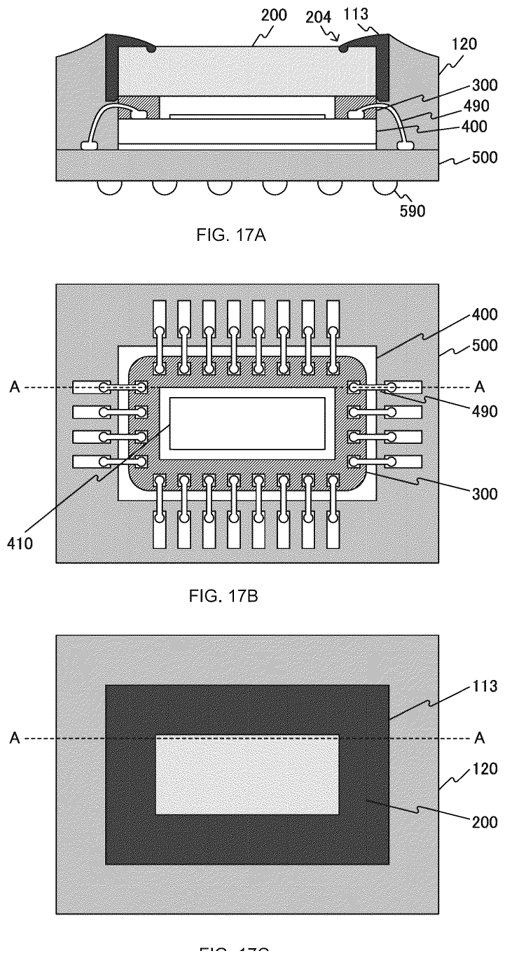

FIG. 17 is a diagram illustrating an example of a structure of an imaging element package according to the fifth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the fifth embodiment, a groove 204 is provided on the upper surface of the sealing glass 200 according to the third embodiment described above. This configuration prevents wet spreading across the upper surface of the sealing glass 200 when a glass protection member 113 is applied. As illustrated in c of the drawing, this groove 204 is provided on the upper surface of the sealing glass 200 along the inner periphery of the glass protection member 113, and has a role in blocking the glass protection member 113.

Note that, in the fifth embodiment, the glass protection member 113 is provided instead of the glass protection member 111 of the third embodiment described above; however, the same material can be used for both. This glass protection member 113 is an example of the protection member recited in the claims.

Furthermore, the present embodiment is similar to the third embodiment described above except that the groove 204 is provided on the upper surface of the sealing glass 200, and thus a detailed description thereof will be omitted.

### Method for Manufacturing Imaging Element Package

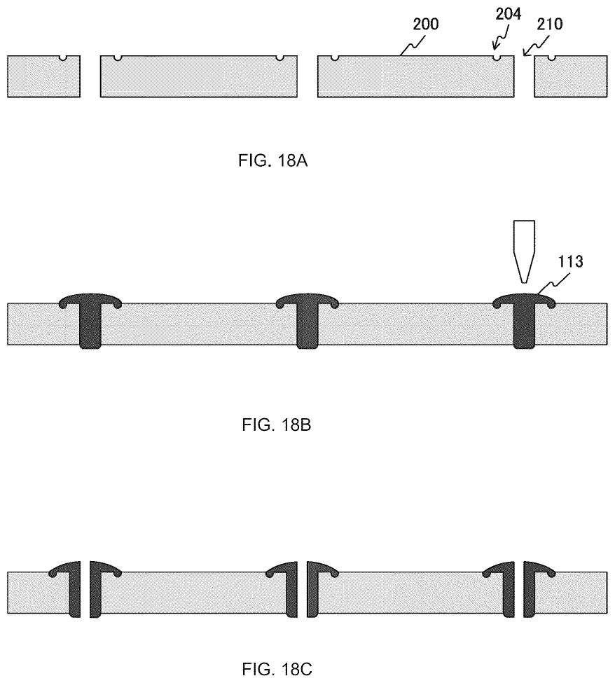

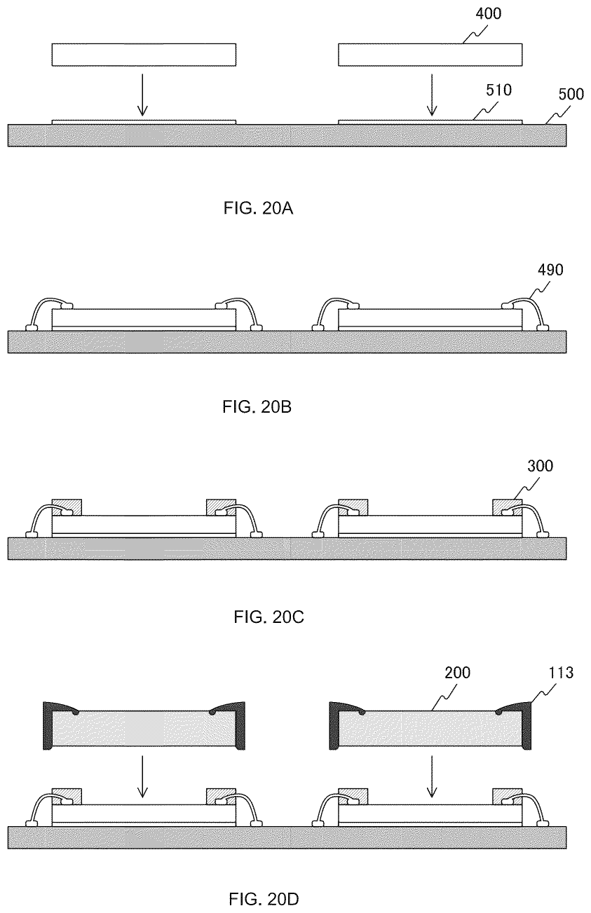

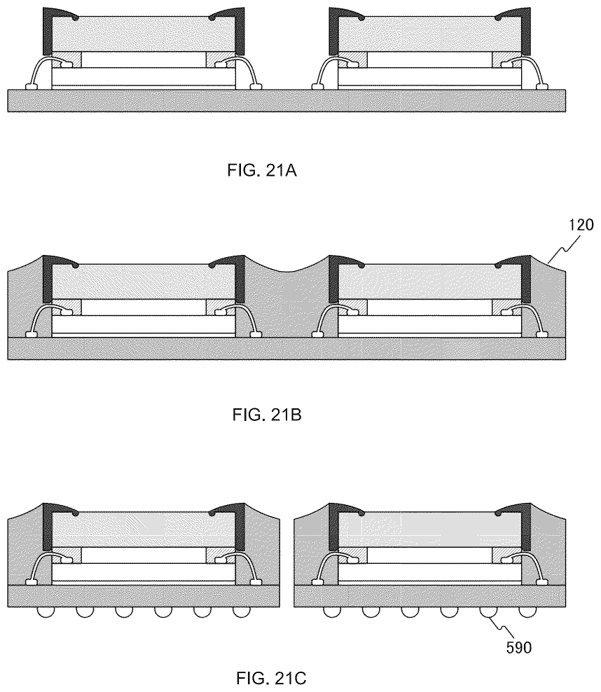

FIGS. 18 to 21 are diagrams illustrating an example of a method for manufacturing the imaging element package according to the fifth embodiment of the present technology.

In the fifth embodiment, similar to the third embodiment described above, it is assumed that the glass protection member 113 is formed before the sealing glass 200 is fixed to the solid-state imaging element 400.

Therefore, as illustrated in a of FIG. 18 and FIG. 19, the glass plate with the dicing tape applied to the back surface undergoes full-cut dicing to form the groove 210 between the sealing glasses 200. Furthermore, the groove 204 for preventing wet spreading is formed inside the groove 210 formed by full-cut dicing.

Then, as illustrated in b of the drawing, the glass protection member 113 is applied to each groove 210 to cover the ridge line of the upper surface and the side surface of the sealing glass 200. At that time, the glass protection member 113 is confined to the area up to the groove 204, preventing further wet spreading. Thereafter, the glass protection member 113 is cured through ultraviolet irradiation or heating, or a combination of ultraviolet irradiation and heating.

Then, as illustrated in c of the drawing, the glass protection member 113 is cut into individual pieces using a dicing blade that is narrower than the blade used for the dicing to ensure that the glass protection member 113 remains on the side surface of the sealing glass 200.

On the other hand, as illustrated in d of the drawing, the solid-state imaging element 400 is mounted on the substrate 500 via the die-bonding resin 510.

Then, as illustrated in e of the drawing, the pads on the solid-state imaging element 400 side and the pads on the substrate 500 side are electrically connected by the bonding wire 490.

Then, as illustrated in f of the drawing, the rib member 300 is applied to the pads on the solid-state imaging element 400 side.

Then, as illustrated in g and h of the drawing, the sealing glass 200 with the glass protection member 113 formed thereon is mounted on the solid-state imaging element 400 via the rib member 300, and the resultant structure is thermally cured.

Thereafter, as illustrated in i of the drawing, the sealing resin 120 is applied to surround the outer periphery of the side surfaces of the solid-state imaging element 400 and the sealing glass 200. However, the sealing resin 120 does not need to cover the ridge line of the upper surface of the sealing glass 200.

Then, as illustrated in j of the drawing, the solder ball 590 is mounted on the lower surface of the substrate 500, and the resultant structure is diced into individual imaging element packages.

As described above, according to the fifth embodiment of the present technology, by forming the groove 204 on the upper surface of the sealing glass 200, it is possible to prevent wet spreading of the glass protection member 113.

### 6. Sixth Embodiment

In the third embodiment described above, it is assumed that the glass protection member 111 covers the entire side surface of the sealing glass 200; however, in the sixth embodiment, it is assumed that the glass protection member covers only the upper part of the side surface of the sealing glass 200. When dicing is performed along a position where the glass protection member is applied to the glass plate, full-cut dicing is required to ensure that the entire side surface of the sealing glass 200 is covered with the glass protection member, but partial dicing is sufficient if only the upper part of the side surface of the sealing glass 200 is covered. This simplifies the manufacturing process of the sealing glass 200.

### Structure of Imaging Element Package

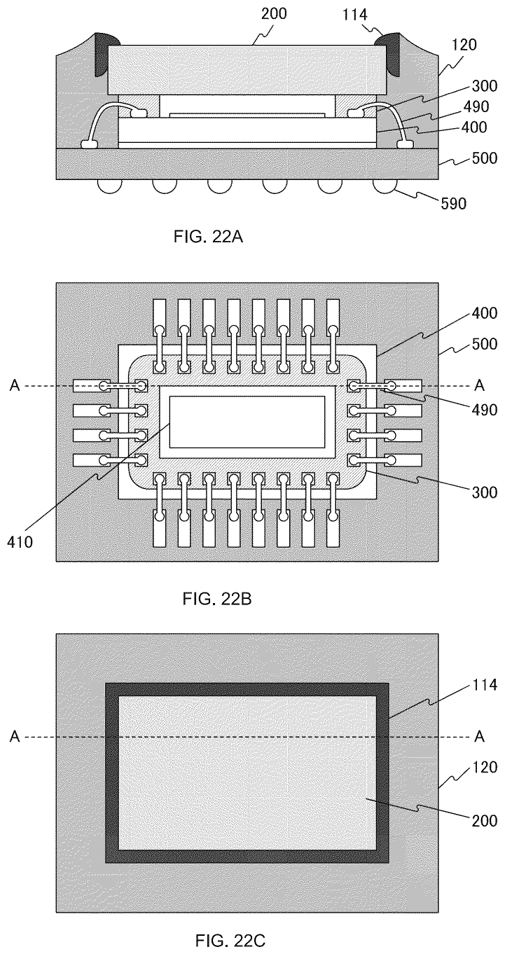

FIG. 22 is a diagram illustrating an example of a structure of an imaging element package according to the sixth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the sixth embodiment, a glass protection member 114 is provided instead of the glass protection member 111 according to the third embodiment described above. The glass protection member 114 according to the sixth embodiment covers only the upper part of the side surface of the sealing glass 200.

Note that, in the sixth embodiment, the glass protection member 114 is provided instead of the glass protection member 111 of the third embodiment described above; however, the same material can be used for both. This glass protection member 114 is an example of the protection member recited in the claims.

Furthermore, the other components are similar to those of the third embodiment described above, and thus a detailed description thereof will be omitted.

### Method for Manufacturing Imaging Element Package

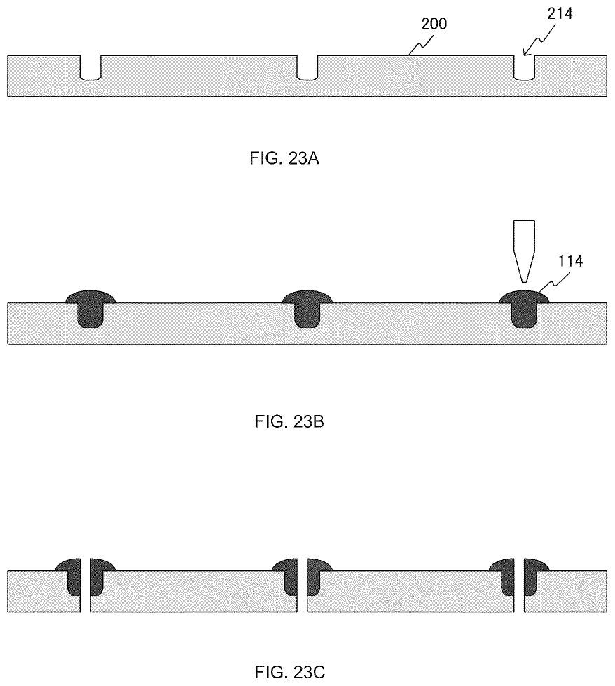

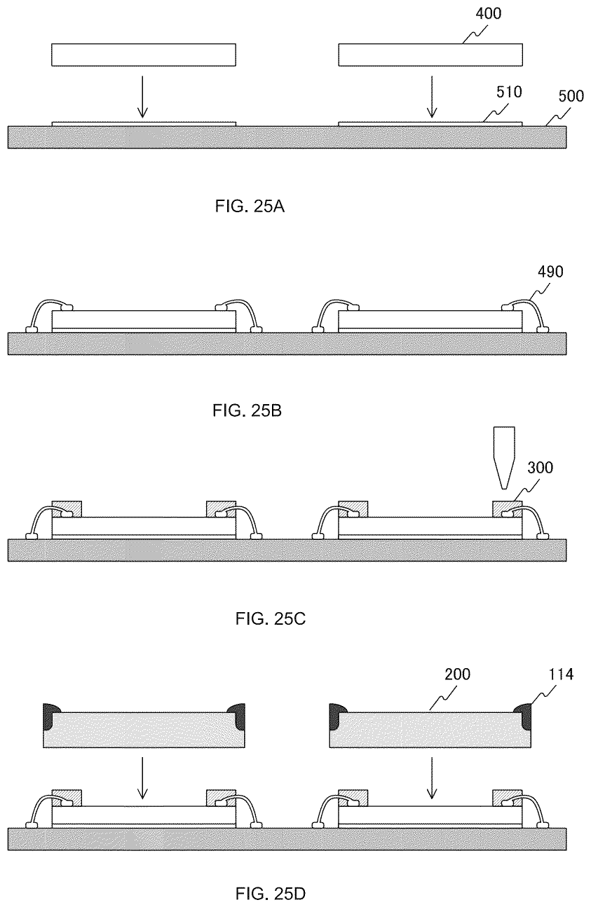

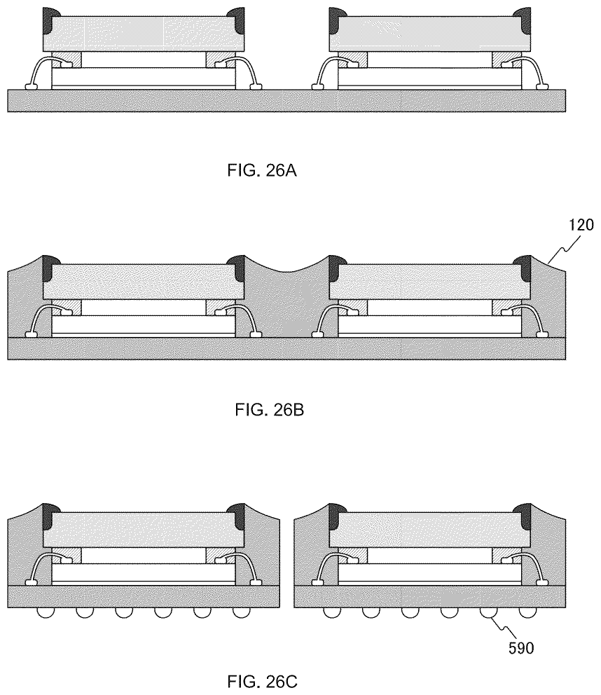

FIGS. 23 to 26 are diagrams illustrating an example of a method for manufacturing the imaging element package according to the sixth embodiment of the present technology.

In the sixth embodiment, similar to the third embodiment described above, it is assumed that the glass protection member 114 is formed before the sealing glass 200 is fixed to the solid-state imaging element 400.

Therefore, as illustrated in a of FIG. 23 and FIG. 24, the glass plate with the dicing tape applied to the back surface undergoes partial dicing to form a groove 214 between the sealing glasses 200.

Then, as illustrated in b of the drawing, the glass protection member 114 is applied to each groove 214 to cover the ridge line of the upper surface and the upper part of the side surface of the sealing glass 200.

Then, as illustrated in c of the drawing, the glass protection member 114 is cut into individual pieces using a dicing blade that is narrower than the blade used for the dicing to ensure that the glass protection member 114 remains on the upper part of the side surface of the sealing glass 200.

On the other hand, as illustrated in d of the drawing, the solid-state imaging element 400 is mounted on the substrate 500 via the die-bonding resin 510.

Then, as illustrated in e of the drawing, the pads on the solid-state imaging element 400 side and the pads on the substrate 500 side are electrically connected by the bonding wire 490.

Then, as illustrated in f of the drawing, the rib member 300 is applied to the pads on the solid-state imaging element 400 side.

Then, as illustrated in g and h of the drawing, the sealing glass 200 with the glass protection member 114 formed thereon is mounted on the solid-state imaging element 400 via the rib member 300, and the resultant structure is thermally cured.

Thereafter, as illustrated in i of the drawing, the sealing resin 120 is applied to surround the outer periphery of the side surfaces of the solid-state imaging element 400 and the sealing glass 200. However, the sealing resin 120 does not need to cover the ridge line of the upper surface of the sealing glass 200.

Then, as illustrated in j of the drawing, the solder ball 590 is mounted on the lower surface of the substrate 500, and the resultant structure is diced into individual imaging element packages.

As described above, according to the sixth embodiment of the present technology, by covering the ridge line of the upper surface and only the upper part of the side surface of the sealing glass 200 with the glass protection member 114, it is possible to facilitate the manufacturing process of the sealing glass 200 while reducing the risk of crack formation.

Note that, according to the sixth embodiment, it is assumed that after the glass protection member 114 is formed on the sealing glass 200, the resultant structure is fixed to the solid-state imaging element 400; however, a similar structure can be formed in a different order. That is, as described in the fourth embodiment described above, a method may be employed where after the sealing glass 200 is fixed to the solid-state imaging element 400, the groove is formed along the outer peripheral portion of the sealing glass 200 using a dicing blade, and the glass protection member 114 is applied. In this case as well, compared to the third embodiment described above, the groove can be formed shallower, which makes the manufacturing process simpler. Furthermore, similar to the fourth embodiment described above, when forming the groove to which the glass protection member 114 is applied, only the sealing resin 120 may be removed by dicing, or a part extending across the boundary between the sealing glass 200 and the sealing resin 120 may be removed.

### 7. Seventh Embodiment

In the third embodiment described above, it is assumed that the sealing glass 200 has a vertical side surface; however, in the seventh embodiment, it is assumed that at least a part of the side surface of the sealing glass has a tapered shape. The tapered side surface of the sealing glass serves to reduce stress applied to the upper surface portion of the sealing glass.

### Structure of Imaging Element Package

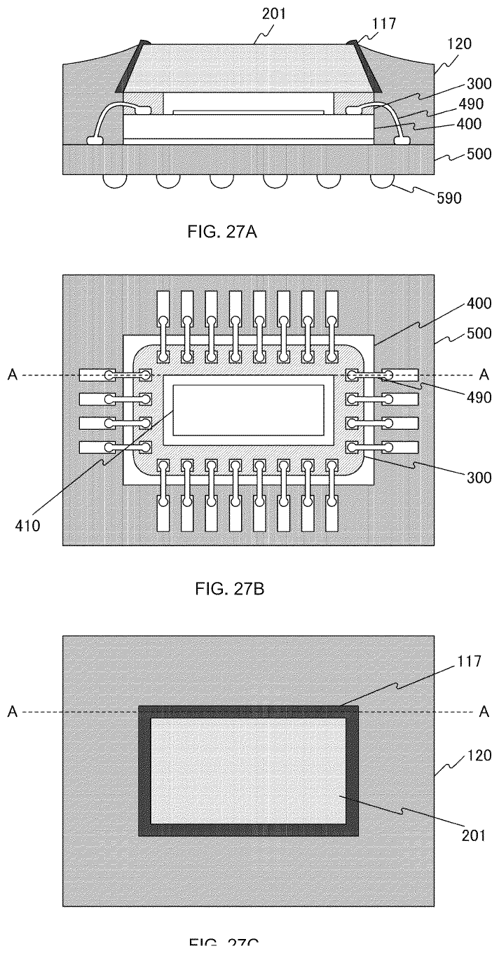

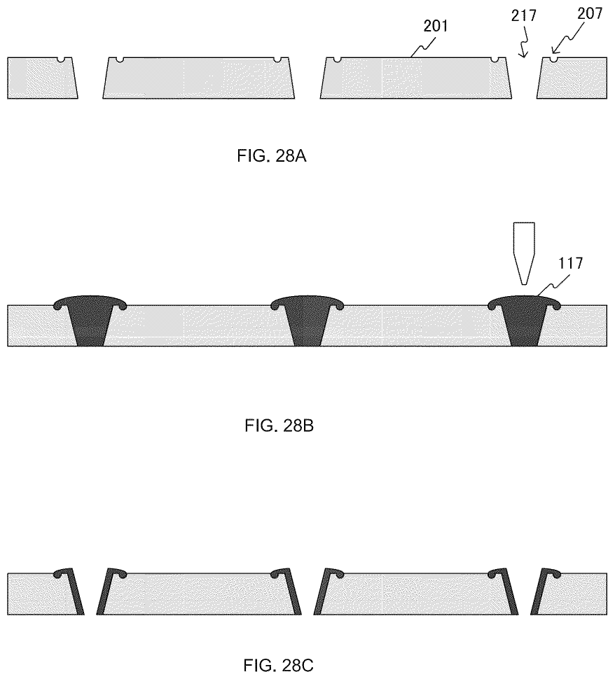

FIG. 27 is a diagram illustrating an example of a structure of an imaging element package according to the seventh embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the seventh embodiment, unlike the third embodiment described above where the sealing glass 200 has a vertical side surface, the sealing glass 201 has a tapered side surface. Accordingly, a glass protection member 117 on the side surface of the sealing glass 201 also has a tapered shape. The more tapered the side surface of the sealing glass 201 is, the less stress is applied to the upper surface of the sealing glass 201.

Note that, in the seventh embodiment, the glass protection member 117 is provided instead of the glass protection member 111 of the third embodiment described above; however, the same material can be used for both. This glass protection member 117 is an example of the protection member recited in the claims. Furthermore, the sealing glass 201 is an example of the transparent member recited in the claims. Furthermore, the other components are similar to those of the third embodiment described above, and thus a detailed description thereof will be omitted.

### Method for Manufacturing Imaging Element Package

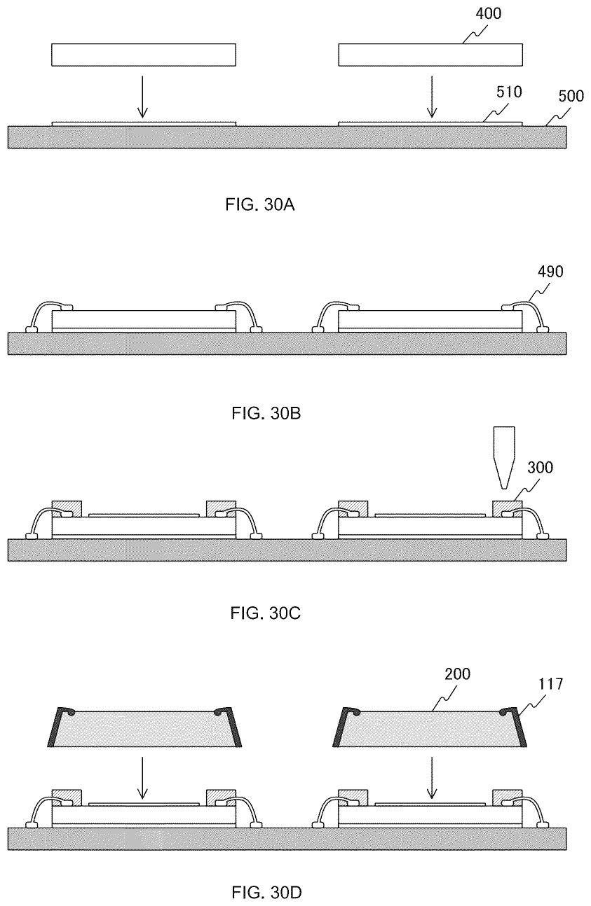

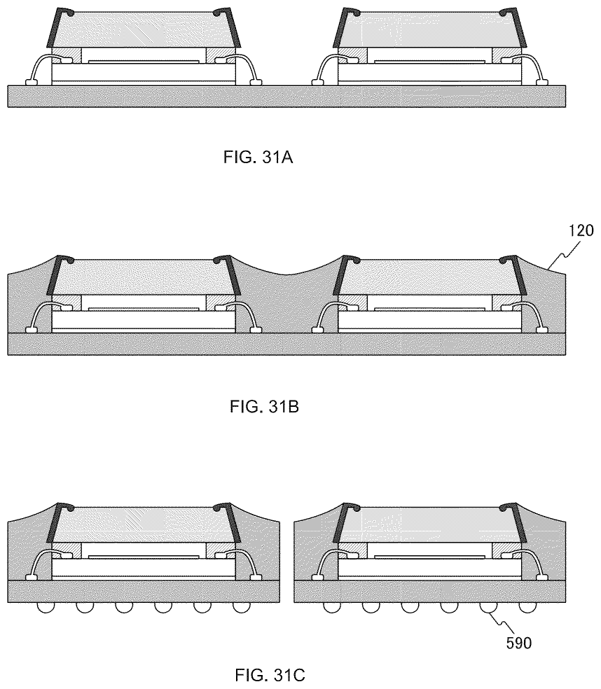

FIGS. 28 to 31 are diagrams illustrating an example of a method for manufacturing the imaging element package according to the seventh embodiment of the present technology.

In the seventh embodiment, since it is assumed that after the sealing glass 201 is fixed to the solid-state imaging element 400, the glass protection member 117 is formed, as illustrated in a of FIG. 28 and FIG. 29, the glass plate with the dicing tape applied to the back surface undergoes full-cut dicing to form a groove 217 between the sealing glasses 201. At this time, the use of a V-shaped blade for dicing forms the side surface of the sealing glass 201 into a tapered shape. Furthermore, similar to the fifth embodiment described above, a groove 207 for preventing wet spreading is formed inside the tapered groove 217. Note that, in addition to dicing, it is also possible to form the tapered groove 217 by laser irradiating of the sealing glass 201, followed by etching.

Then, as illustrated in b of the drawing, the glass protection member 117 is applied to each groove 217 to cover the ridge line of the upper surface and the side surface of the sealing glass 201. At that time, the glass protection member 117 is confined to the area up to the groove 217, preventing further wet spreading. Thereafter, the glass protection member 117 is cured through ultraviolet irradiation or heating, or a combination of ultraviolet irradiation and heating.

Then, as illustrated in c of the drawing, the sealing glass 201 is cut into individual pieces using a V-shaped blade to ensure that the glass protection member 117 remains on the tapered side surface of the sealing glass 201.

On the other hand, as illustrated in d of the drawing, the solid-state imaging element 400 is mounted on the substrate 500 via the die-bonding resin 510.

Then, as illustrated in e of the drawing, the pads on the solid-state imaging element 400 side and the pads on the substrate 500 side are electrically connected by the bonding wire 490.

Then, as illustrated in f of the drawing, the rib member 300 is applied to the pads on the solid-state imaging element 400 side.

Then, as illustrated in g and h of the drawing, the sealing glass 201 with the glass protection member 117 formed thereon is mounted on the solid-state imaging element 400 via the rib member 300, and the resultant structure is thermally cured.

Thereafter, as illustrated in i of the drawing, the sealing resin 120 is applied to surround the outer periphery of the side surfaces of the solid-state imaging element 400 and the sealing glass 201. However, the sealing resin 120 does not need to cover the ridge line of the upper surface of the sealing glass 201.

Then, as illustrated in j of the drawing, the solder ball 590 is mounted on the lower surface of the substrate 500, and the resultant structure is diced into individual imaging element packages.

As described above, according to the seventh embodiment of the present technology, by forming the side surface of the sealing glass 201 into a tapered shape, it is possible to reduce stress applied to the upper surface portion of the sealing glass 201, thereby reducing the risk of crack formation. Note that, in the above-described example, the entire side surface of the sealing glass 201 is tapered; however, as illustrated in the following modification, only a part of the side surface may be tapered, or the side surface may be tapered at a plurality of different angles.

### First Modification of Seventh Embodiment

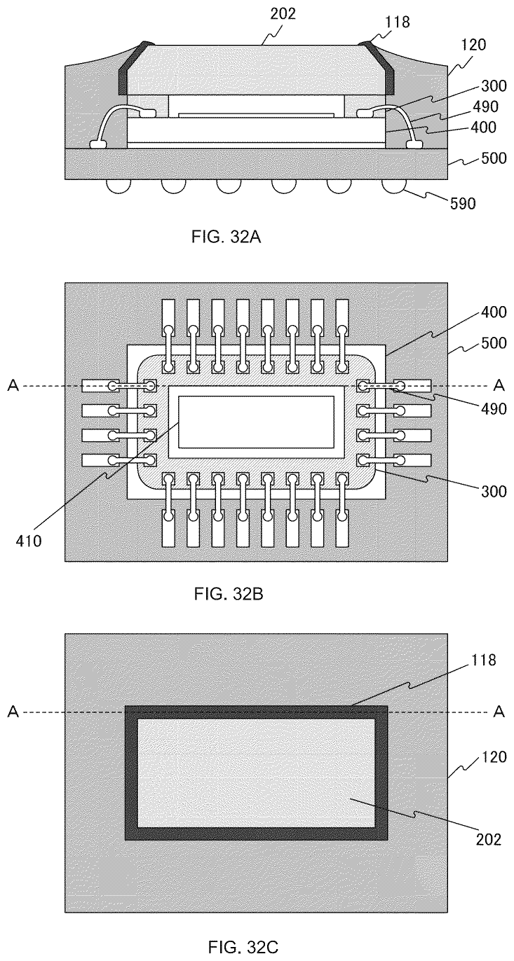

FIG. 32 is a diagram illustrating an example of a structure of an imaging element package according to the first modification of the seventh embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the first modification, of the side surface of the sealing glass 202, the upper part to which the highest stress is applied has a tapered shape, and the lower part has a normal vertical shape. Then, a glass protection member 118 also has a shape conforming to the side surface of the sealing glass 202.

Note that, in the first modification, the glass protection member 118 is provided instead of the glass protection member 117 of the seventh embodiment described above; however, the same material can be used for both. This glass protection member 118 is an example of the protection member recited in the claims. Furthermore, the other components are similar to those of the seventh embodiment described above, and thus a detailed description thereof will be omitted.

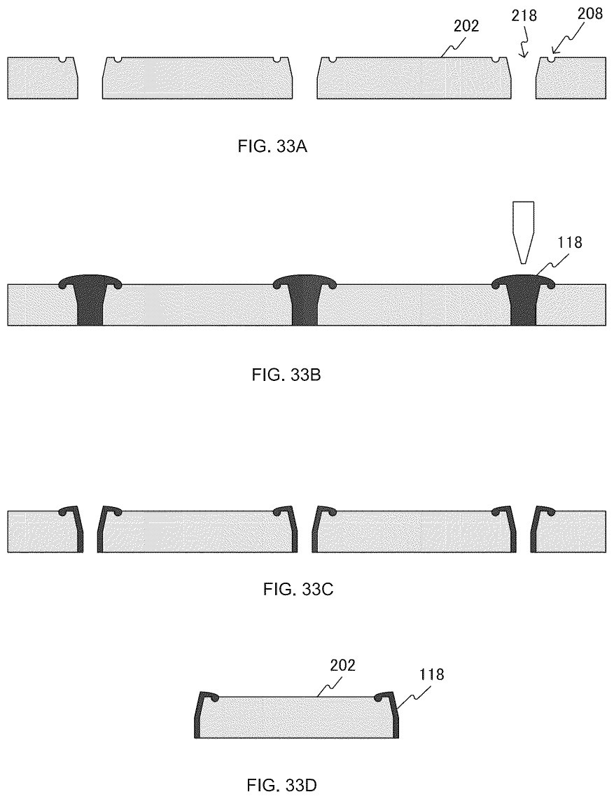

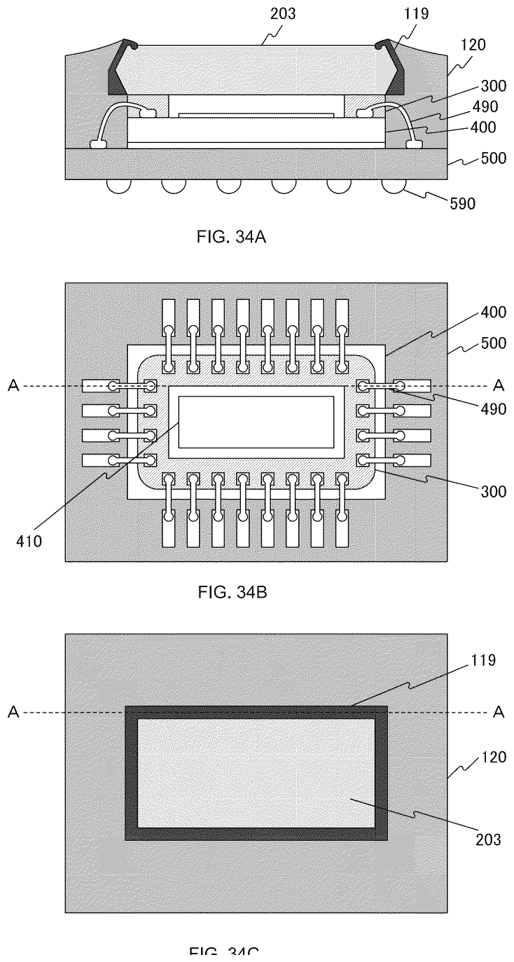

FIG. 33 is a diagram illustrating an example of a method for manufacturing the sealing glass 202 according to the first modification of the seventh embodiment of the present technology.

First, as illustrated in a of the drawing, the glass plate with the dicing tape applied to the back surface undergoes full-cut dicing and then undergoes partial dicing using a V-shaped blade to form a groove 218 between the sealing glasses 202. Furthermore, similar to the seventh embodiment described above, a groove 208 for preventing wet spreading is formed inside the tapered groove 218. Note that, in addition to dicing, it is also possible to form the tapered groove 218 by laser irradiating of the sealing glass 202, followed by etching.

Then, as illustrated in b of the drawing, the glass protection member 118 is applied to each groove 218 to cover the ridge line of the upper surface and the side surface of the sealing glass 202. At that time, the glass protection member 118 is confined to the area up to the groove 218, preventing further wet spreading. Thereafter, the glass protection member 118 is cured through ultraviolet irradiation or heating, or a combination of ultraviolet irradiation and heating.

Then, as illustrated in c of the drawing, the sealing glass 202 undergoes full-cut dicing to ensure that the glass protection member 118 remains on the tapered side surface of the sealing glass 202 and then undergoes partial dicing using a V-shaped blade, resulting in individual cut pieces as illustrated in d of the drawing.

Note that the mounting of the sealing glass 202 including the glass protection member 118 on the solid-state imaging element 400 is similar to the seventh embodiment described above, and thus a detailed description of the subsequent procedure will be omitted.

### Second Modification of Seventh Embodiment

FIG. 34 is a diagram illustrating an example of a structure of an imaging element package according to the second modification of the seventh embodiment of the present technology. Of the drawing, a is a cross-sectional view of the imaging element package taken along line A-A. Of the drawing, b and care top views of the imaging element package. Note that b of the drawing illustrates a state where the sealing glass and the sealing resin are removed.

In the second modification, the upper and lower parts of the side surface of the sealing glass 203 have different tapered shapes. Then, a glass protection member 119 also has a shape conforming to the side surface of the sealing glass 203.

Note that, in the second modification, the glass protection member 119 is provided instead of the glass protection member 117 of the seventh embodiment described above; however, the same material can be used for both. This glass protection member 119 is an example of the protection member recited in the claims. Furthermore, the other components are similar to those of the seventh embodiment described above, and thus a detailed description thereof will be omitted.

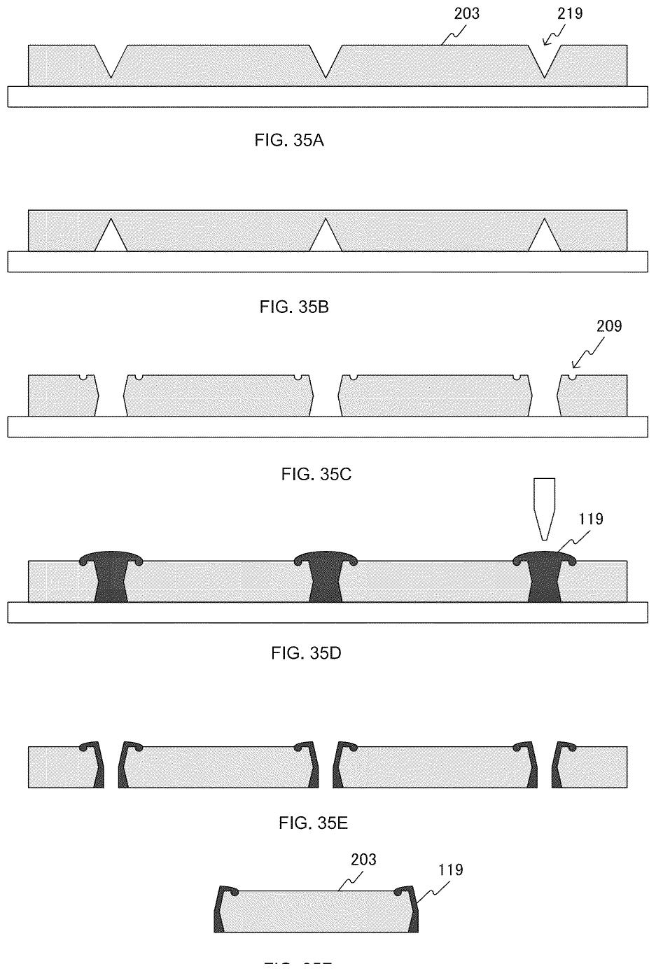

FIG. 35 is a diagram illustrating an example of a method for manufacturing the sealing glass 203 according to the second modification of the seventh embodiment of the present technology.

First, as illustrated in a of the drawing, the glass plate with the dicing tape applied to the back surface undergoes partial dicing using a V-shaped blade to form a groove 219 between the sealing glasses 203.

Then, as illustrated in b of the drawing, the glass plate is inverted and then undergoes dicing using the V-shaped blade from the opposite side. As a result, as illustrated in c of the drawing, individual sealing glasses 203 are obtained. Furthermore, similar to the seventh embodiment described above, a groove 209 for preventing wet spreading is formed inside the tapered groove 219. Note that, in addition to dicing, it is also possible to form the tapered groove 219 by laser irradiating of the sealing glass 203, followed by etching.

Then, as illustrated in d of the drawing, the glass protection member 119 is applied to each groove 219 to cover the ridge line of the upper surface and the side surface of the sealing glass 203. At that time, the glass protection member 119 is confined to the area up to the groove 219, preventing further wet spreading. Thereafter, the glass protection member 119 is cured through ultraviolet irradiation or heating, or a combination of ultraviolet irradiation and heating.

Then, as illustrated in e of the drawing, the sealing glass 203 undergoes full-cut dicing to ensure that the glass protection member 119 remains on the tapered side surface of the sealing glass 203 and then undergoes partial dicing using a V-shaped blade, resulting in individual cut pieces as illustrated in f of the drawing.

Note that the mounting of the sealing glass 203 including the glass protection member 119 on the solid-state imaging element 400 is similar to the seventh embodiment described above, and thus a detailed description of the subsequent procedure will be omitted.

### 8. Eighth Embodiment

In the first embodiment described above, the sealing resin 130 is formed to cover the ridge line 299 of the upper surface of the sealing glass 200. In the eighth embodiment, in a structure where the sealing resin 130 covers the ridge line 299 of the upper surface of the sealing glass 200, a recess is provided on the upper surface of the sealing resin 130 at a position separated from the upper surface of the sealing glass 200, and a low-elasticity resin is embedded in the recess.

### Structure of Imaging Element Package

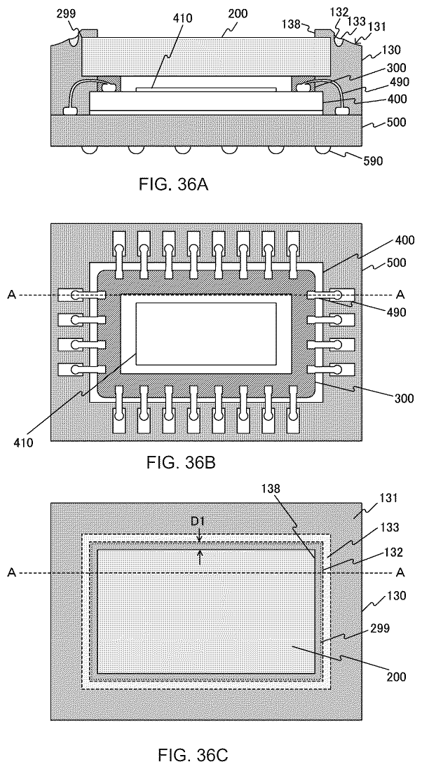

FIG. 36 is a diagram illustrating an example of a structure of an imaging element package according to the eighth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

In the drawing, in this imaging element package, a recess 132 is added to the sealing resin 130 of the first embodiment described above. In the recess 132, a low-elasticity resin 133 is embedded. The other components of the imaging element package of the eighth embodiment are similar to those of the imaging element package of the first embodiment described above.

The recess 132 is positioned on an upper surface 131 of the sealing resin 130, separated from the upper surface of the sealing glass 200. The upper surface 131 of the sealing resin 130 may be inclined or may include a curved surface. Here, the ridge line 299 of the upper surface of the sealing glass 200 is covered with the sealing resin 130. At this time, the sealing resin 130 may be positioned over the entire side surface of the sealing glass 200 and around the upper surface of the sealing glass 200. An end 138 of the sealing resin 130 on the upper surface of the sealing glass 200 may be provided at a position where vignetting of incident light received by a light receiving region 410 of the solid-state imaging element 400 does not occur. At this time, the end 138 of the sealing resin 130 may be provided at a position where the vicinity of the ridge line 299, which is the starting point of crack formation in the sealing glass 200, is covered. For example, the end 138 of the sealing resin 130 may be placed at a distance ranging from 10 μm or longer and 100 μm or shorter from the ridge line 299. The height of the sealing resin 130 on the upper surface of the sealing glass 200 is preferably set to a value that reduces stress applied to the starting point of crack formation in the sealing glass 200 while maintaining impact resistance. For example, the height of the sealing resin 130 on the upper surface of the sealing glass 200 may be set within the range of 10 μm or longer and 100 μm or shorter. Here, the ridge line 299 refers to the boundary between the upper surface and the side surface of the sealing glass 200.

In the light receiving region 410, pixels are arranged in a matrix in a row direction and a column direction. In the light receiving region 410, a color filter and an on-chip lens may be arranged for each pixel.

The recess 132 may be continuously formed to surround the periphery of the sealing glass 200. The depth of the recess 132 may be set so as not to reach the bonding wire 490. A distance D1 between the recess 132 and the sealing glass 200 may be uniform across the periphery of the sealing glass 200 or may be different for each side of the sealing glass 200. The recess 132 may have a groove shape. For example, the recess 132 may be a U-shaped groove. The recess 132 may be a notch. The sealing resin 130 may be formed by molding, coating, dispensing, potting, or 3D printing.

The elastic modulus of the low-elasticity resin 133 is set lower than that of the sealing resin 130. The low-elasticity resin 133 may be formed flush with the upper surface 131 of the sealing resin 130, may be raised above the upper surface 131 of the sealing resin 130, or may be formed below the upper surface 131 of the sealing resin 130. The low-elasticity resin 133 may be a silicon-based resin. The low-elasticity resin 133 may be formed by coating, dispensing, potting, or 3D printing.

Note that, in the eighth embodiment, an example where the bonding wire 490 is embedded in the rib member 300 on the solid-state imaging element 400 has been described. Alternatively, the bonding wire 490 is not necessarily embedded in the rib member 300, and may be positioned outside the rib member 300.

In the eighth embodiment, the sealing glass 200 is used as an example of the transparent member, but the transparent member may be a quartz substrate or a transparent resin substrate such as acrylic or polycarbonate. As the transparent member, Al₂O₃, CaF₂, MgF₂, LiF, or the like may be selected on the basis of the wavelength of light received by the solid-state imaging element 400.

### Method for Manufacturing Imaging Element Package

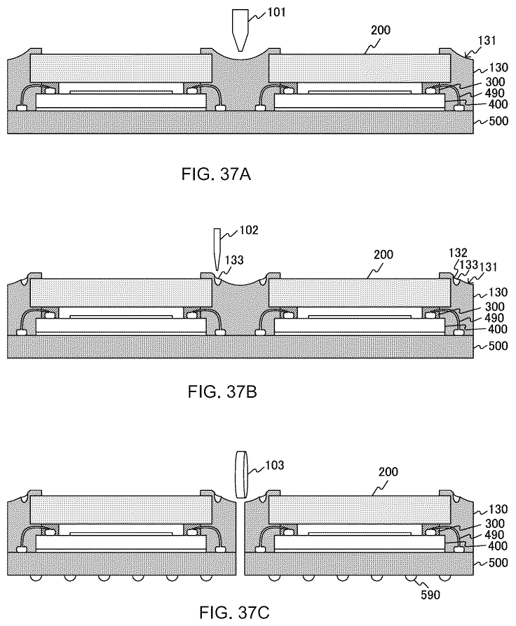

FIG. 37 is a cross-sectional view illustrating an example of a method for manufacturing the imaging element package according to the eighth embodiment of the present technology.

Similar to the process illustrated in FIG. 3, the sealing glass 200 formed by cutting the glass plate into pieces of glass is mounted on the solid-state imaging element 400 via the rib member 300, and the resultant structure is thermally cured. At this time, the substrate 500 acts as a common substrate for a plurality of imaging element packages. In this process, the substrate 500 has a mounting region defined for each solid-state imaging element 400.

Next, as illustrated in a of FIG. 37, the sealing resin 130 is dispensed from a nozzle 101 into a space between the solid-state imaging elements 400 to cover the bonding wire 490 on the substrate 500. At this time, the sealing resin 130 covers both the side surface of the sealing glass 200 and the ridge line 299 of the upper surface of the sealing glass 200.

Next, as illustrated in b of FIG. 37, the low-elasticity resin 133 is dispensed from a nozzle 102 to the upper surface 131 of the sealing resin 130. The low-elasticity resin 133 may be dispensed before the sealing resin 130 is cured, or may be dispensed after the sealing resin 130 is cured. In the method where the low-elasticity resin 133 is dispensed before the sealing resin 130 is cured, the low-elasticity resin 133 can be injected into the sealing resin 130 on the basis of the momentum of the low-elasticity resin 133 discharged from the nozzle 102. At this time, the recess 132 can be formed through the impact of the low-elasticity resin 133 on the sealing resin 130, which eliminates the need to form the recess 132 before dispensing the low-elasticity resin 133. In the method where the low-elasticity resin 133 is dispensed after the sealing resin 130 is cured, the recess 132 is formed in the sealing resin 130 before the low-elasticity resin 133 is dispensed. At this time, the sealing resin 130 and the low-elasticity resin 133 can be formed by replacing the nozzles 101 and 102 attached to the dispenser.

Next, as illustrated in c of FIG. 37, after the solder ball 590 is mounted on the lower surface of the substrate 500, the sealing resin 130 and the substrate 500 are cut for each imaging element package through dicing using a blade 103.

As described above, according to the eighth embodiment of the present technology, the recess 132 is provided on the upper surface 131 of the sealing resin 130 at a position separated from the upper surface of the sealing glass 200, and the low-elasticity resin 133 is embedded in the recess 132. Here, the ridge line 299 of the upper surface of the sealing glass 200 is covered with the sealing resin 130. This configuration can divide the stress applied to the upper surface portion of the sealing glass 200 via the sealing resin 130 at the position of the recess 132 while keeping the maximum stress point away from the vicinity of the ridge line 299 of the upper surface of the sealing glass 200, which is the starting point of crack formation. It is therefore possible to reduce the stress applied to the starting point of crack formation in the sealing glass 200, thereby reducing the risk of crack formation in the sealing glass 200. At this time, by embedding the low-elasticity resin 133 in the recess 132, it is possible to suppress a deterioration of sealing performance caused by the recess 132 while dividing the stress applied to the upper surface portion of the sealing glass 200 at the position of the recess 132.

### 9. Ninth Embodiment

In the eighth embodiment described above, in the structure where the sealing resin 130 covers the ridge line 299 of the upper surface of the sealing glass 200, the recess 132 is provided on the upper surface of the sealing resin 130 at a position separated from the upper surface of the sealing glass 200, and the low-elasticity resin 133 is embedded in the recess 132. In the ninth embodiment, in the structure where the sealing resin 130 covers the ridge line 299 of the upper surface of the sealing glass 200, the recess is provided on the upper surface of the sealing resin 130 at a position separated from the upper surface of the sealing glass 200.

### Structure of Imaging Element Package

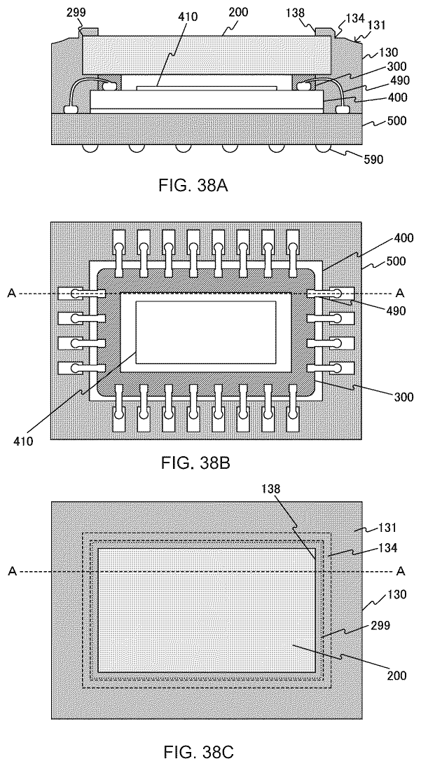

FIG. 38 is a diagram illustrating an example of a structure of an imaging element package according to the ninth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

This imaging element package includes a recess 134 instead of the recess 132 of the eighth embodiment described above. Furthermore, this imaging element package is not provided with the low-elasticity resin 133 of the eighth embodiment described above. The other components of the imaging element package of the ninth embodiment are similar to those of the imaging element package of the eighth embodiment described above.

The recess 134 is positioned on the upper surface 131 of the sealing resin 130, separated from the upper surface of the sealing glass 200. The recess 134 may be continuously formed to surround the periphery of the sealing glass 200. The upper surface 131 of the sealing resin 130 may be inclined. At this time, the recess 134 may include a surface perpendicular to the side surface of the sealing glass 200 and a surface parallel to the side surface. With this configuration, it is possible to form the recess 134 on the upper surface 131 of the sealing resin 130 through half-cutting using a blade. Note that the recess 134 may be a groove or a notch.

### Method for Manufacturing Imaging Element Package

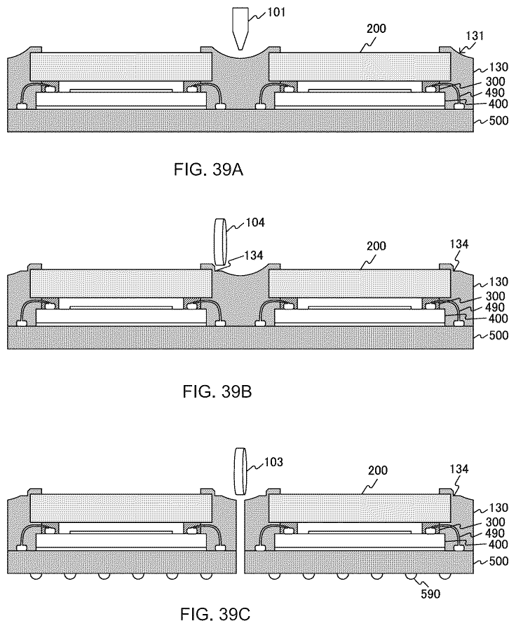

FIG. 39 is a cross-sectional view illustrating an example of a method for manufacturing the imaging element package according to the ninth embodiment of the present technology.

Similar to the process illustrated in FIG. 3, the sealing glass 200 formed by cutting the glass plate into pieces of glass is mounted on the solid-state imaging element 400 via the rib member 300, and the resultant structure is thermally cured.

Next, as illustrated in a of FIG. 39, the sealing resin 130 is dispensed from the nozzle 101 into a space between the solid-state imaging elements 400 to cover the bonding wire 490 on the substrate 500.

Next, as illustrated in b of FIG. 39, the recess 134 is formed on the upper surface 131 of the sealing resin 130 through half-cutting of the sealing resin 130 using a blade 104. Note that, to form the recess 134 on the upper surface 131 of the sealing resin 130, laser processing or 3D printing may be used.

Next, as illustrated in c of FIG. 39, after the solder ball 590 is mounted on the lower surface of the substrate 500, the sealing resin 130 and the substrate 500 are cut for each imaging element package through dicing using the blade 103. At this time, by replacing the blades 103 and 104 attached to the dicing device, the formation of the recess 134 and the fragmentation into individual imaging element packages can be achieved.

As described above, according to the ninth embodiment of the present technology, the recess 134 is provided on the upper surface 131 of the sealing resin 130 at a position separated from the upper surface of the sealing glass 200. Here, the ridge line 299 of the upper surface of the sealing glass 200 is covered with the sealing resin 130. This configuration can reduce the stress applied to the starting point of crack formation in the sealing glass 200, thereby reducing the risk of crack formation in the sealing glass 200.

### 10. Tenth Embodiment

In the eighth embodiment described above, in the structure where the sealing resin 130 covers the ridge line 299 of the upper surface of the sealing glass 200, the recess 132 is provided on the upper surface of the sealing resin 130 at a position separated from the upper surface of the sealing glass 200, and the low-elasticity resin 133 is embedded in the recess 132. In the tenth embodiment, in a structure where the sealing resin covers the side surface of the sealing glass 200, the recess 132 is provided on the upper surface of the sealing resin at a position separated from the upper surface of the sealing glass 200, and the low-elasticity resin 133 is embedded in the recess 132.

### Structure of Imaging Element Package

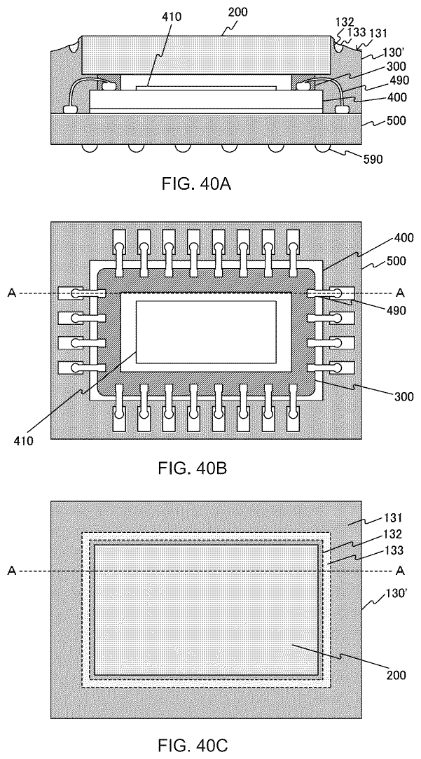

FIG. 40 is a diagram illustrating an example of a structure of an imaging element package according to the tenth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

This imaging element package includes a sealing resin 130′ instead of the sealing resin 130 of the eighth embodiment described above. The other components of the imaging element package of the tenth embodiment are similar to those of the imaging element package of the eighth embodiment described above.

The sealing resin 130′ covers the side surface of the sealing glass 200. The sealing resin 130′ may cover the entire side surface of the sealing glass 200, or may cover a part of the side surface of the sealing glass 200. Here, the sealing resin 130′ does not cover the upper surface of the sealing glass 200. At this time, the upper surface of the sealing glass 200 is entirely exposed from the sealing resin 130′. The other configurations of the sealing resin 130′ of the tenth embodiment are similar to those of the sealing resin 130 of the eighth embodiment described above.

At this time, the recess 132 is formed on the upper surface 131 of the sealing resin 130′ at a position separated from the upper surface of the sealing glass 200. In the recess 132, the low-elasticity resin 133 is embedded.

### Method for Manufacturing Imaging Element Package

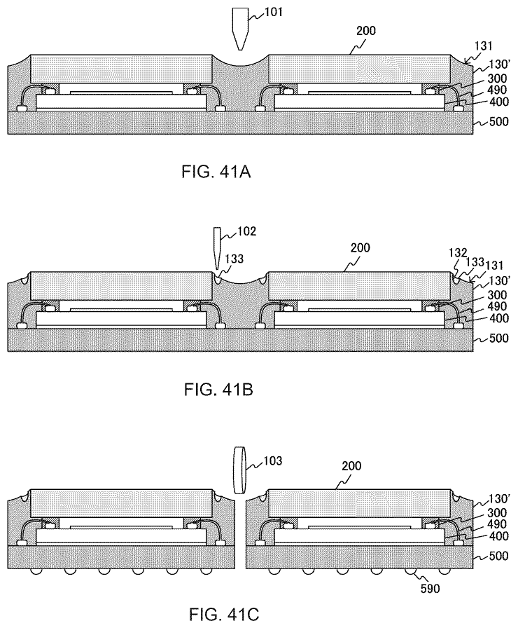

FIG. 41 is a cross-sectional view illustrating an example of a method for manufacturing the imaging element package according to the tenth embodiment of the present technology.

The method for manufacturing the imaging element package according to the tenth embodiment is similar to the method for manufacturing the imaging element package according to the eighth embodiment described above except that the sealing resin 130′ is used instead of the sealing resin 130.

That is, similar to the process illustrated in FIG. 3, the sealing glass 200 formed by cutting the glass plate into pieces of glass is mounted on the solid-state imaging element 400 via the rib member 300, and the resultant structure is thermally cured.

Next, as illustrated in a of FIG. 41, the sealing resin 130′ is dispensed from the nozzle 101 into a space between the solid-state imaging elements 400 to cover the bonding wire 490 on the substrate 500.

Next, as illustrated in b of FIG. 41, the low-elasticity resin 133 is dispensed from the nozzle 102 to the upper surface 131 of the sealing resin 130′.

Next, as illustrated in c of FIG. 41, after the solder ball 590 is mounted on the lower surface of the substrate 500, the sealing resin 130′ and the substrate 500 are cut for each imaging element package through dicing using the blade 103.

As described above, according to the tenth embodiment of the present technology, the recess 132 is provided on the upper surface 131 of the sealing resin 130′ at a position separated from the upper surface of the sealing glass 200, and the low-elasticity resin 133 is embedded in the recess 132. This configuration can divide the stress applied to the upper surface portion of the sealing glass 200 via the sealing resin 130′ at the position of the recess 132, thereby suppressing a deterioration of sealing performance caused by the recess 132 while reducing the risk of crack formation in the sealing glass 200.

### 11. Eleventh Embodiment

In the ninth embodiment described above, in the structure where the sealing resin 130 covers the ridge line 299 of the upper surface of the sealing glass 200, the recess 134 is provided on the upper surface of the sealing resin 130 at a position separated from the upper surface of the sealing glass 200. In the eleventh embodiment, in the structure where the sealing resin covers the side surface of the sealing glass 200, the recess 134 is provided on the upper surface of the sealing resin at a position separated from the upper surface of the sealing glass 200.

### Structure of Imaging Element Package

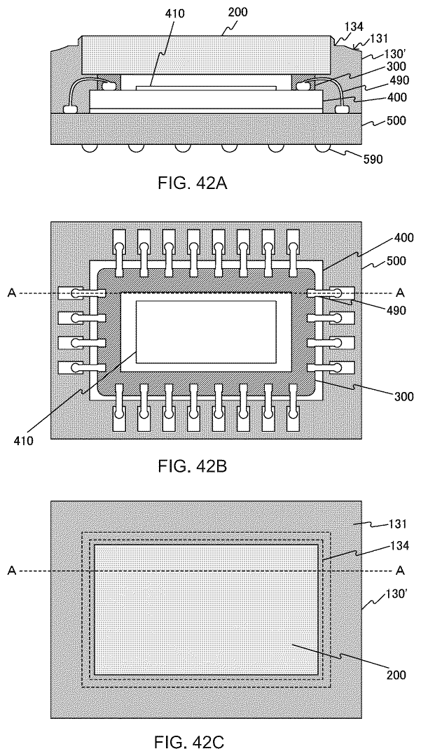

FIG. 42 is a diagram illustrating an example of a structure of an imaging element package according to the eleventh embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

This imaging element package includes the sealing resin 130′ of the tenth embodiment described above instead of the sealing resin 130 of the ninth embodiment described above. The other components of the imaging element package of the eleventh embodiment are similar to those of the imaging element package of the ninth embodiment described above.

The sealing resin 130′ covers the side surface of the sealing glass 200. Here, the sealing resin 130′ does not cover the upper surface of the sealing glass 200. At this time, the recess 134 is formed on the upper surface 131 of the sealing resin 130′ at a position separated from the upper surface of the sealing glass 200.

### Method for Manufacturing Imaging Element Package

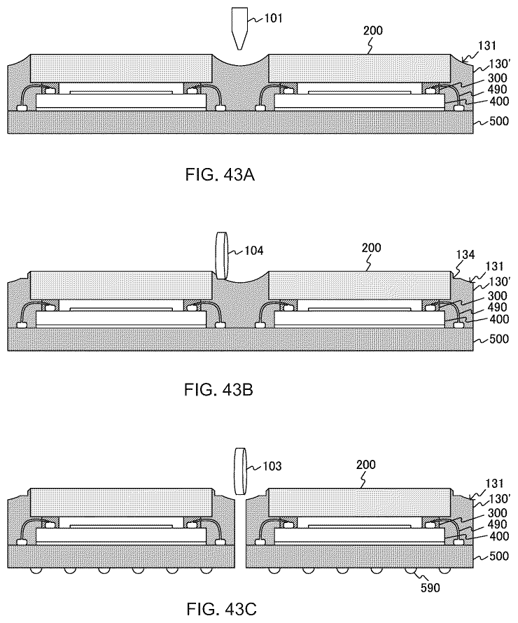

FIG. 43 is a cross-sectional view illustrating an example of a method for manufacturing the imaging element package according to the eleventh embodiment of the present technology.

The method for manufacturing the imaging element package according to the eleventh embodiment is similar to the method for manufacturing the imaging element package according to the ninth embodiment described above except that the sealing resin 130′ is used instead of the sealing resin 130.

That is, similar to the process illustrated in FIG. 3, the sealing glass 200 formed by cutting the glass plate into pieces of glass is mounted on the solid-state imaging element 400 via the rib member 300, and the resultant structure is thermally cured.

Next, as illustrated in a of FIG. 43, the sealing resin 130′ is dispensed from the nozzle 101 into a space between the solid-state imaging elements 400 to cover the bonding wire 490 on the substrate 500.

Next, as illustrated in b of FIG. 43, the recess 134 is formed on the upper surface 131 of the sealing resin 130′ through half-cutting of the sealing resin 130′ using the blade 104.

Next, as illustrated in c of FIG. 43, after the solder ball 590 is mounted on the lower surface of the substrate 500, the sealing resin 130′ and the substrate 500 are cut for each imaging element package through dicing using the blade 103.

As described above, according to the eleventh embodiment of the present technology, in the structure where the sealing resin 130′ covers the side surface of the sealing glass 200, the recess 134 is provided on the upper surface 131 of the sealing resin 130′ at a position separated from the upper surface of the sealing glass 200. This configuration can divide the stress applied to the upper surface portion of the sealing glass 200 via the sealing resin 130′ at the position of the recess 134, thereby reducing the risk of crack formation in the sealing glass 200.

### 12. Twelfth Embodiment

In the eleventh embodiment described above, in the structure where the sealing resin 130′ covers the side surface of the sealing glass 200, the recess 134 is provided on the upper surface of the sealing resin 130′ at a position separated from the upper surface of the sealing glass 200. In the twelfth embodiment, in the structure where the sealing resin covers the side surface of the sealing glass 200, the recess is formed on the upper surface of the sealing resin at a position separated from the upper surface of the sealing glass 200 through molding along with the sealing resin.

### Structure of Imaging Element Package

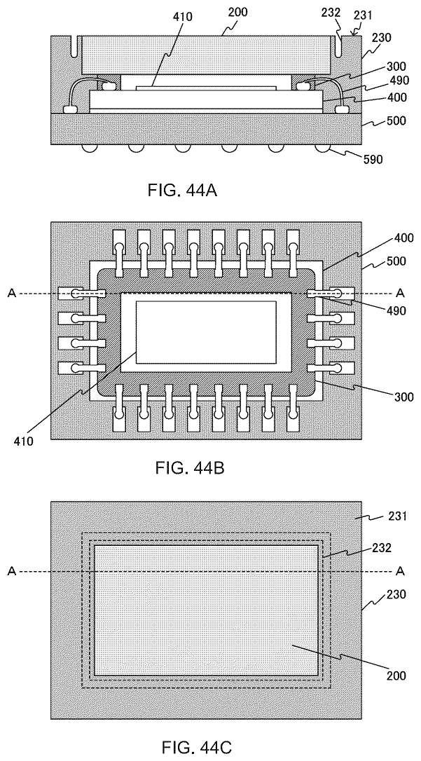

FIG. 44 is a diagram illustrating an example of a structure of an imaging element package according to the twelfth embodiment of the present technology. Of the drawing, a is a cross-sectional view of the imaging element package taken along line A-A. Of the drawing, b and c are top views of the imaging element package. Note that b of the drawing illustrates a state where the sealing glass and the sealing resin are removed.

This imaging element package includes a sealing resin 230 instead of the sealing resin 130′ of the eleventh embodiment described above. The other components of the imaging element package of the twelfth embodiment are similar to those of the imaging element package of the eleventh embodiment described above.

The sealing resin 230 covers the side surface of the sealing glass 200. At this time, the sealing resin 230 does not cover the upper surface of the sealing glass 200. Furthermore, an upper surface 231 of the sealing resin 230 is planarized. At this time, the upper surface 231 of the sealing resin 230 and the upper surface of the sealing glass 200 may be positioned on the same plane. At this time, the recess 232 is formed on the upper surface 231 of the sealing resin 230 at a position separated from the upper surface of the sealing glass 200.

A molding resin is used as the material of the sealing resin 230. As the molding resin, a thermosetting resin such as an epoxy resin may be used. At this time, the sealing resin 230 and the recess 232 may be simultaneously formed through molding.

### Method for Manufacturing Imaging Element Package

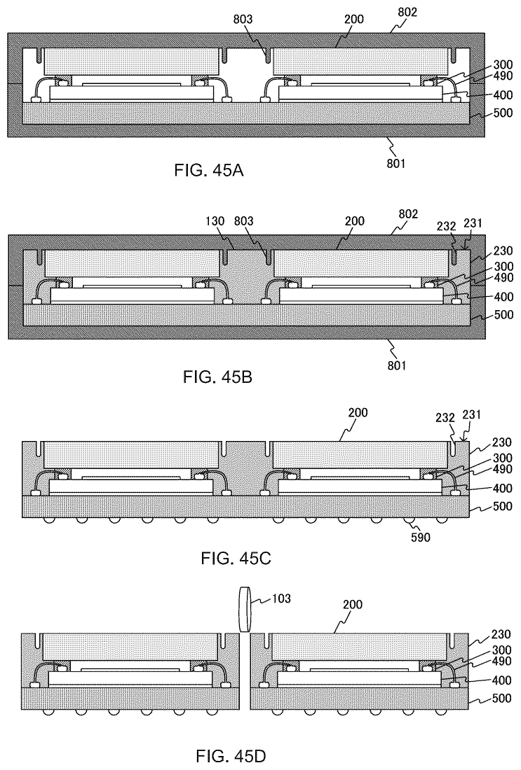

FIG. 45 is a cross-sectional view illustrating an example of a method for manufacturing the imaging element package according to the twelfth embodiment of the present technology.

Similar to the process illustrated in FIG. 3, the sealing glass 200 formed by cutting the glass plate into pieces of glass is mounted on the solid-state imaging element 400 via the rib member 300, and the resultant structure is thermally cured.

Next, as illustrated in a of FIG. 45, the substrate 500 including the solid-state imaging element 400 on which the sealing glass 200 is mounted via the rib member 300 is placed in molds 801 and 802. The lower surface of the substrate 500 is in contact with the lower surface in the mold 801. The upper surface of the sealing glass 200 is in contact with the upper surface in the mold 801. Here, in the mold 802, a protrusion 803 is formed at a position where the recess 232 is formed on the sealing resin 230. The outer surface of the protrusion 803 can be matched to the inner surface of the recess 232. The molds 801 and 802 can be vertically separated.

Next, as illustrated in b of FIG. 45, the sealing resin 230 is injected into the molds 801 and 802 and cured, thereby forming the sealing resin 230 between the solid-state imaging elements 400 and the recess 232 on the upper surface 231 of the sealing resin 230. Note that the molding of the sealing resin 230 may be performed using either transfer molding or compression molding.

Next, as illustrated in c of FIG. 45, the sealing resin 230 and the recess 232 are simultaneously formed through molding, and then the molds 801 and 802 are removed.

Next, as illustrated in d of FIG. 45, after the solder ball 590 is mounted on the lower surface of the substrate 500, the sealing resin 230 and the substrate 500 are cut for each imaging element package through dicing using the blade 103.

As described above, according to the twelfth embodiment of the present technology, in the structure where the sealing resin 230 covers the side surface of the sealing glass 200, the recess 232 is formed on the upper surface of the sealing resin 230 at a position separated from the upper surface of the sealing glass 200 through molding along with the sealing resin 230. This configuration can divide the stress applied to the upper surface portion of the sealing glass 200 via the sealing resin 230 at the position of the recess 232, thereby reducing the risk of crack formation in the sealing glass 200. At this time, the sealing resin 230 and the recess 232 can be simultaneously formed through molding, and the number of processes can be reduced, compared to a method where the sealing resin 230 is formed through dispensing and the recess 232 is formed through dicing.

Note that, in the twelfth embodiment as well, the low-elasticity resin 133 may be embedded in the recess 232, similar to the tenth embodiment described above. Furthermore, in the twelfth embodiment as well, the sealing resin 230 may cover the ridge line 299 of the upper surface of the sealing glass 200, similar to the eighth embodiment described above. As the method for covering, through molding, the ridge line 299 of the upper surface of the sealing glass 200 using the sealing resin 230, for example, the molding of the sealing resin 230 may be performed after a protective tape is applied to a part of the upper surface of the sealing glass 200 that is not covered with the sealing resin 230.

### 13. Thirteenth Embodiment

In the tenth embodiment described above, the recess 132 is provided on the upper surface 131 of the sealing resin 130 at a position separated from the upper surface of the sealing glass 200, and the low-elasticity resin 133 is embedded in the recess 132. In the thirteenth embodiment, the position of the recess on the upper surface of the sealing resin, separated from the upper surface of the sealing glass is optimized on the basis of the configuration of the imaging element package.

### Structure of Imaging Element Package

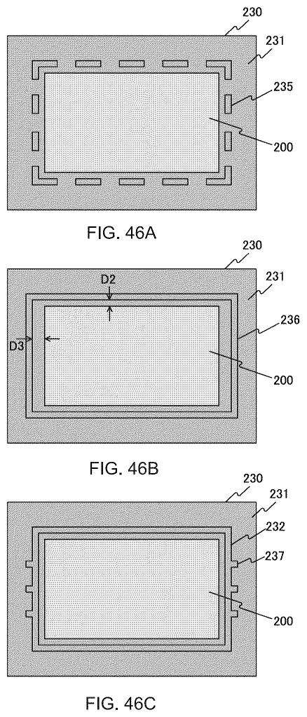

FIG. 46 is a plan view illustrating an example of a structure of an imaging element package according to the thirteenth embodiment of the present technology. Of the drawing, a is a plan view illustrating a first example of the imaging element package according to the thirteenth embodiment. Of the drawing, b is a plan view illustrating a second example of the imaging element package according to the thirteenth embodiment. Of the drawing, c is a plan view illustrating a third example of the imaging element package according to the thirteenth embodiment.

As illustrated in a of the drawing, the first example of the imaging element package includes a recess 235 instead of the recess 232 of the twelfth embodiment described above. The other components of the imaging element package of the first example of the thirteenth embodiment are similar to those of the imaging element package of the twelfth embodiment described above.

The recess 235 is positioned on the upper surface 231 of the sealing resin 230, separated from the upper surface of the sealing glass 200. Here, the recess 235 is provided along a part of the periphery of the sealing glass 200. At this time, the recess 235 may be provided at a position where the uniformity of stress applied to the upper surface of the sealing glass 200 is improved. For example, the recess 235 may be intermittently provided to surround the periphery of the sealing glass 200. The recess 235 need not be provided at a position facing each corner of the sealing glass 200. Alternatively, the recess 235 may be provided only at the center of each side of the sealing glass 200. At this time, to improve the uniformity of stress applied to the upper surface of the sealing glass 200, it is preferable that the recess 235 be provided on both sides of the sealing glass 200 in a line-symmetrical manner. The width or depth of the recess 235 may be adjusted on the basis of the position of the recess 235.

As illustrated in b of the drawing, the second example of the imaging element package includes a recess 236 instead of the recess 232 of the twelfth embodiment described above. The other components of the imaging element package of the second example of the thirteenth embodiment are similar to those of the imaging element package of the twelfth embodiment described above.

The recess 236 is positioned on the upper surface 231 of the sealing resin 230, separated from the upper surface of the sealing glass 200. Here, the recess 236 is continuously provided to surround the periphery of the sealing glass 200. At this time, the distance between the recess 236 and the sealing glass 200 may vary in a manner that depends on each side of the sealing glass 200. For example, the distance from the recess 236 may be shortened on the side experiencing greater stress from the sealing resin 230. For example, in a case where the long side of the sealing glass 200 experiences greater stress than the short side, a distance D2 between the recess 236 and the long side of the sealing glass 200 may be shorter than a distance D3 between the recess 236 and the short side of the sealing glass 200.

In c of the drawing, in the third example of the imaging element package, a recess 237 is added to the imaging element package of the twelfth embodiment described above. The other components of the imaging element package of the third example of the thirteenth embodiment are similar to those of the imaging element package of the twelfth embodiment described above.

The recess 237 is formed at a right angle to the side surface of the sealing glass 200. The recess 237 may be formed at an angle to the side surface of the sealing glass 200. At this time, the recess 237 may be in contact with the outside of the recess 232. Furthermore, the recess 237 may be provided on the side of the sealing glass 200 experiencing greater stress from the sealing resin 230, or may be provided only at the center of the side.

As described above, according to the thirteenth embodiment of the present technology, the position of the recess on the upper surface 231 of the sealing resin 230, separated from the upper surface of the sealing glass 200 is optimized on the basis of the configuration of the imaging element package. This makes it possible to set the position of the recess in accordance with the size and material of each part of the imaging element package, which improves the uniformity of stress applied to the upper surface of the sealing glass 200. It is therefore possible to reduce stress concentration on the upper surface of the sealing glass 200, thereby reducing the risk of crack formation in the sealing glass 200.

Note that, in the thirteenth embodiment as well, the low-elasticity resin 133 may be embedded in each recess 235, 236, 237, similar to the tenth embodiment described above. Furthermore, in the thirteenth embodiment as well, the sealing resin 230 may cover the ridge line 299 of the upper surface of the sealing glass 200, similar to the eighth embodiment described above.

Furthermore, in the embodiment described above, the imaging element package in which the imaging element is packaged has been used as an example, but the present technology is not necessarily limited to such an imaging element package, and may be applied to a hollow package in which an optical element is packaged. The optical element may be a light receiving element, a light emitting element, a display element, or micro electro mechanical systems (MEMS). The light receiving element may be an image sensor such as a CMOS image sensor or a single photon avalanche diode (SPAD) sensor. The light received by the image sensor may be visible light, near infrared light (NIR), short wavelength infrared light (SWIR), ultraviolet light, X-rays, or the like. The optical element may be a light receiving element such as a photo diode (PD) or a light emitting element such as a laser diode (LD), a light emitting diode (LED), or a vertical cavity surface emitting laser (VCSEL). The optical element may be an optical switch, a digital micromirror device (DMD), or the like. The optical element may be a display element such as a liquid crystal element or an organic electro luminescence (EL) element. The material used for the optical element may be a semiconductor such as Si, GaAS, or InGaAsP, or a dielectric such as LiNbO₃, glass, or a transparent resin.

Furthermore, the embodiments described above show examples for embodying the present technology, and the respective matters in the embodiments and the respective matters specifying the invention in the claims have correspondence relationships. Similarly, the matters specifying the invention in the claims and matters with the same names in the embodiments of the present technology have correspondence relationships. However, the present technology is not limited to the embodiments, and can be embodied by applying various modifications to the embodiments without departing from the scope of the present technology.

Furthermore, the procedures described in the above-described embodiments may be considered as a method including a series of procedures and may be considered as a program for allowing a computer to execute the series of procedures and a recording medium which stores the program. As this recording medium, for example, a compact disc (CD), a MiniDisc (MD), a digital versatile disc (DVD), a memory card, a Blu-ray (registered trademark) disc, and the like can be used.

Note that the effects described in the present specification are merely examples and are not limited, and other effects may also be achieved.

Note that the present technology may also have the following configurations.
(1) An imaging element package including:
a solid-state imaging element;
a substrate where the solid-state imaging element is mounted;
a transparent member fixed to an imaging surface side of the solid-state imaging element; and
a protection member that covers a ridge line of an upper surface of the transparent member.
(2) The imaging element package according to the above (1), in which
the protection member includes a sealing resin that covers a side surface of the transparent member and a side surface of the solid-state imaging element.
(3) The imaging element package according to the above (2), further including a protruding member provided on the upper surface of the transparent member, along an inner periphery of the protection member.
(4) The imaging element package according to the above (1), further including
a sealing resin that covers at least a side surface of the solid-state imaging element, in which
the protection member is provided between the sealing resin and the solid-state imaging element.
(5) The imaging element package according to the above (4), in which
the protection member includes a low-elasticity resin.
(6) The imaging element package according to the above (4) or (5), in which
the transparent member includes a groove provided on the upper surface of the transparent member, along an inner peripheral portion of the protection member.
(7) The imaging element package according to any one of the above (4) to (6), in which
the protection member entirely covers a side surface of the transparent member.
(8) The imaging element package according to any one of the above (4) to (6), in which
the protection member covers only an upper side portion of a side surface of the transparent member.
(9) The imaging element package according to any one of the above (4) to (8), in which
at least a part of a side surface of the transparent member has a tapered shape.
(10) The imaging element package according to any one of the above (1) to (9), further including
a recess positioned on an upper surface of the protection member, separated from the upper surface of the transparent member.
(11) The imaging element package according to the above (10), further including a low-elasticity resin that is embedded in the recess and has a lower elastic modulus than the protection member.
(12) The imaging element package according to the above (10) or (11), in which
the recess is provided in a position surrounding a periphery of the transparent member.
(13) The imaging element package according to the above (10) or (11), in which
the recess is provided along a part of a periphery of the transparent member.
(14) The imaging element package according to any one of the above (10) to (13), in which
the recess has a groove shape.
(15) The imaging element package according to the above (10), in which
the recess is formed in a vertical or inclined direction relative to a side surface of the transparent member.
(16) A method for manufacturing an imaging element package, the method including:
mounting a solid-state imaging element on a substrate;
fixing a transparent member to an imaging surface side of the solid-state imaging element; and
forming a protection member that covers a ridge line of an upper surface of the transparent member.
(17) The method for manufacturing an imaging element package according to the above (16), in which
the forming a protection member includes:
forming a sealing resin that covers a side surface of the solid-state imaging element;
forming a groove by removing a part of the sealing resin; and
applying the protection member to the groove.
(18) The method for manufacturing an imaging element package according to the above (16), in which
the forming a protection member includes:
forming a sealing resin that covers a side surface of the solid-state imaging element;
forming a groove by removing a part extending across a boundary between the sealing resin and the transparent member; and
applying the protection member to the groove.
(19) The method for manufacturing an imaging element package according to any one of the above (16) to (18), further including forming a recess on an upper surface of the protection member at a position separated from the upper surface of the transparent member.
(20) A method for manufacturing an imaging element package, the method including:
forming a protection member that covers a ridge line of an upper surface of a transparent member; and
fixing the transparent member to an imaging surface side of a solid-state imaging element mounted on a substrate.
(21) An imaging element package including:
a solid-state imaging element;
a substrate where the solid-state imaging element is mounted;
a transparent member fixed to an imaging surface side of the solid-state imaging element;
a protection member that covers a side surface of the transparent member, and
a recess positioned on an upper surface of the protection member, separated from an upper surface of the transparent member.
(22) The imaging element package according to the above (21), further including a low-elasticity resin that is embedded in the recess and has a lower elastic modulus than the protection member.
(23) The imaging element package according to the above (21) or (22), in which
the recess is provided in a position surrounding a periphery of the transparent member.
(24) The imaging element package according to the above (21) or (22), in which
the recess is provided along a part of a periphery of the transparent member.
(25) The imaging element package according to the above (24), in which
the recess is provided in a position where the uniformity of stress applied to the upper surface of the transparent member is enhanced.
(26) The imaging element package according to any one of the above (21) to (25), in which
the recess has a groove shape.
(27) The imaging element package according to any one of the above (21) to (26), in which the transparent member includes a molding resin.
(28) A method for manufacturing an imaging element package, the method including:
mounting a solid-state imaging element on a substrate;
fixing a transparent member to an imaging surface side of the solid-state imaging element;
forming a protection member that covers a side surface of the transparent member, and
forming a recess on an upper surface of the protection member at a position separated from an upper surface of the transparent member.
(29) The method for manufacturing an imaging element package according to (28), in which
the protection member and the recess are formed through molding of the protection member.

### REFERENCE SIGNS LIST

111 to 119 Glass protection member
120, 130 Sealing resin
129 Groove
200 to 203 Sealing glass
204, 207 to 210, 214, 217 to 219 Groove
220 Dam
299 Ridge line
300 Rib member
400 Solid-state imaging element
490 Bonding wire
500 Substrate
510 Die-bonding resin
590 Solder ball
700 Protective tape

1. An imaging element package comprising:
a solid-state imaging element;
a substrate where the solid-state imaging element is mounted;
a transparent member fixed to an imaging surface side of the solid-state imaging element; and
a protection member that covers a ridge line of an upper surface of the transparent member.

2. The imaging element package according to claim 1, wherein
the protection member includes a sealing resin that covers a side surface of the transparent member and a side surface of the solid-state imaging element.

3. The imaging element package according to claim 2, further comprising a protruding member provided on the upper surface of the transparent member, along an inner periphery of the protection member.

4. The imaging element package according to claim 1, further comprising
a sealing resin that covers at least a side surface of the solid-state imaging element, wherein
the protection member is provided between the sealing resin and the solid-state imaging element.

5. The imaging element package according to claim 4, wherein
the protection member includes a low-elasticity resin.

6. The imaging element package according to claim 4, wherein
the transparent member includes a groove provided on the upper surface of the transparent member, along an inner peripheral portion of the protection member.

7. The imaging element package according to claim 4, wherein
the protection member entirely covers a side surface of the transparent member.

8. The imaging element package according to claim 4, wherein
the protection member covers only an upper side portion of a side surface of the transparent member.

9. The imaging element package according to claim 4, wherein
at least a part of a side surface of the transparent member has a tapered shape.

10. The imaging element package according to claim 1, further comprising
a recess positioned on an upper surface of the protection member, separated from the upper surface of the transparent member.

11. The imaging element package according to claim 10, further comprising a low-elasticity resin that is embedded in the recess and has a lower elastic modulus than the protection member.

12. The imaging element package according to claim 10, wherein
the recess is provided in a position surrounding a periphery of the transparent member.

13. The imaging element package according to claim 10, wherein
the recess is provided along a part of a periphery of the transparent member.

14. The imaging element package according to claim 10, wherein
the recess has a groove shape.

15. The imaging element package according to claim 10, wherein
the recess is formed in a vertical or inclined direction relative to a side surface of the transparent member.

16. A method for manufacturing an imaging element package, the method comprising:
mounting a solid-state imaging element on a substrate;
fixing a transparent member to an imaging surface side of the solid-state imaging element; and
forming a protection member that covers a ridge line of an upper surface of the transparent member.

17. The method for manufacturing an imaging element package according to claim 16, wherein
the forming a protection member includes:
forming a sealing resin that covers a side surface of the solid-state imaging element;
forming a groove by removing a part of the sealing resin; and
applying the protection member to the groove.

18. The method for manufacturing an imaging element package according to claim 16, wherein
the forming a protection member includes:
forming a sealing resin that covers a side surface of the solid-state imaging element;
forming a groove by removing a part extending across a boundary between the sealing resin and the transparent member; and
applying the protection member to the groove.

19. The method for manufacturing an imaging element package according to claim 16, further comprising forming a recess on an upper surface of the protection member at a position separated from the upper surface of the transparent member.

20. A method for manufacturing an imaging element package, the method comprising:
forming a protection member that covers a ridge line of an upper surface of a transparent member; and
fixing the transparent member to an imaging surface side of a solid-state imaging element mounted on a substrate.
